(19) United States
(12) Patent Application Publication
(10) Pub. No.: US 2019/0032909 A1
(43) Pub. Date: Jan. 31, 2019

(54) RADIATOR, ELECTRONIC DEVICE, ILLUMINATION DEVICE, AND METHOD FOR MANUFACTURING RADIATOR

(71) Applicant: JNC CORPORATION, TOKYO (JP)

(72) Inventors: Shin KOGA, CHIBA (JP); Masako HINATSU, CHIBA (JP); Kento UJIIYE, CHIBA (JP); Yasuhiro SHIRAISHI, CHIBA (JP)

(73) Assignee: JNC CORPORATION, TOKYO (JP)

(21) Appl. No.: 15/777,211

(22) PCT Filed: Nov. 11, 2016
(86) PCT No.: PCT/JP2016/083461

§ 371 Date: Oct. 8, 2018

(30) Foreign Application Priority Data
Nov. 20, 2015 (JP) 2015-227595

(51) Int. Cl. F21V 29/503; F21V 29/76; F21V 29/85; F21V 29/87; F21V 29/89

(52) U.S. Cl. CPC F21V 29/503; F21V 29/76; H01L 23/3672; F21V 29/87; F21V 29/89; F21V 29/86

(57) ABSTRACT

The invention relates to a radiator, an electronic device, an illumination device, and a method for manufacturing the radiator. The radiator has two or more heat dissipation fins. The heat dissipation fins each are a laminate including metal foil, a graphite sheet and metal foil in that order. All the heat dissipation fins included in the radiator each have a join surface joined with adjacent heat dissipation fins, and a non-contact part not in contact with the adjacent heat dissipation fins. At least two of the heat dissipation fins each included in the radiator has a blade portion having a predetermined angle with respect to the join surface in at least part of the non-contact part.

### TECHNICAL FIELD

The invention relates to a radiator preferably used for dissipating heat generated in an illumination device or an electronic device, a method for manufacturing the radiator, and so forth.

### BACKGROUND ART

In an electronic device including a computer and so forth, and an illumination device including LED and so forth, a heating value has increased in association with achievement of high performance. For example, the heating value is particularly large in a central processing unit (CPU) mounted in the electronic device and a LED lamp. A radiator is generally installed in order to cool elements included the devices to a specified temperature or lower. In the radiator, a size is increased for responding to an increase of the heating value in association with achievement of a high speed of the CPU or achievement of high density of an illumination light source, and simultaneously weight is increased by an increase in the number of fins constituting the radiator. Thus, if the weight of the radiator is increased, transport of the electronic device is liable to become difficult, and simultaneously an excessive load is liable to be applied to the electronic device or the illumination device in which the radiator is installed. Moreover, the increase of weight of the radiator to be mounted in an automobile or the like causes deterioration of fuel consumption.

Existing radiators have been produced by integral molding by die-casting or produced by machining of aluminum or magnesium. Above all, there are problems, in the integral molding by die-casting, such that reducing a thickness of fins or increasing a height thereof is limited, and therefore sufficient performance as the radiator is unable to be developed, and in the machining, such that cost is increased and mass production is not suitable.

For the above, a lightweight radiator without reducing heat dissipation performance is required to be provided, and as one means therefor, studies have been conducted on using graphite having high thermal conductivity comparable to or higher than the conductivity of copper or the like, and density lower than the density of copper for a material used for the radiator.

As a technique relating to such a radiator using graphite, a radiator having a region in which a graphite sheet and a metal plate are laminated, and bent into a waveform or a corrugated form is known, for example (see Patent literature Nos. 1 and 2).

Moreover, Patent literature No. 3 describes a radiator having a region in which a laminate prepared by covering both surfaces of a graphite sheet with metal foil is bent into a corrugated form.

### CITATION LIST

### Patent Literature

Patent literature No. 1: JP 2002-329987 A

Patent literature No. 2: JP 2009-99878 A

Patent literature No. 3: JP 2015-46557 A

### SUMMARY OF INVENTION

### Technical Problem

In the radiators disclosed in Patent literature Nos. 1 and 2, a graphite sheet exists on a surface of the radiator, and graphite is brittle in a several-fold layer structure, thereby easily causing disintegrated powder of the graphite. Such disintegrated powder of graphite causes a short circuit or the like, and therefore suppression of scattering of the powder is required in an electronic device or an illumination device. Therefore, when the radiator is used in the electronic device or the illumination device, a whole surface of the graphite sheet is required to be protected with a film or the like in order to suppress scattering of the powder. However, as a result, the film used for protection of the graphite sheet causes heat resistance, and an effect of laminating the graphite sheet and the metal plate has been unable to be sufficiently obtained.

Moreover, the radiator described in Patent literature No. 3 has been lightweight, but room for further improvement has remained in view of heat dissipation and strength.

An embodiment of the invention provides a radiator that is lightweight and excellent in heat dissipation efficiency by suppressing scattering and falling of the powder due to brittleness of graphite while taking advantage of excellent thermal conductivity of graphite.

### Solution to Problem

The configuration example of the invention is as described below.

Item 1. A radiator, including two or more heat dissipation fins, wherein,

the heat dissipation fins each are a laminate including metal foil, a graphite sheet and metal foil in that order,

all the heat dissipation fins included in the radiator each have a join surface joined with adjacent heat dissipation fins, and a non-contact part not in contact with the adjacent heat dissipation fins to each other, and

at least two of the heat dissipation fins each included in the radiator has a blade portion having a predetermined angle with respect to the join surface in at least part of the non-contact part.

Item 2. The radiator according to item 1, wherein an area of the non-contact part is larger than an area of the join surface in all the heat dissipation fins included in the radiator.

Item 3. The radiator according to item 1 or 2, wherein a ratio (H/L) of a maximum length H of the radiator in a direction substantially perpendicular to the join surface to a maximum length L thereof in a direction substantially horizontal to the join surface is 1.0 or more.

Item 4. The radiator according to any one of items 1 to 3, wherein the laminate has flexibility.

Item 5. The radiator according to any one of items 1 to 4, wherein the predetermined angle is 30 to 150 degrees.

Item 6. The radiator according to any one of items 1 to 5, wherein the heat dissipation fin is formed by folding the laminate, and has a substantially L shape, a substantially U shape, a substantially concave shape or a substantially fan shape when a state of folding the heat dissipation fin is viewed from the front.

Item 7. The radiator according to any one of items 1 to 6, wherein all the heat dissipation fins included in the radiator each are joined with adjacent heat dissipation fins using an adhesive tape, an adhesive, grease or cream solder.

Item 8. The radiator according to any one of items 1 to 7, wherein the graphite sheet is a sheet made of natural graphite or artificial graphite.

Item 9. The radiator according to any one of items 1 to 8, wherein thermal conductivity of the sheet in an in-plane direction in the graphite sheet is 500 W/m·K or more.

Item 10. The radiator according to any one of items 1 to 9, wherein the metal foil is copper, aluminum, titanium or magnesium foil.

Item 11. The radiator according to any one of items 1 to 10, wherein a thickness of the metal foil is smaller than a thickness of the graphite sheet.

Item 12. The radiator according to any one of items 1 to 11, wherein the heat dissipation fin has a heat dissipation coating layer including orthorhombic silicate and a resin binder on at least part of a surface layer thereof.

Item 13. The radiator according to item 12, wherein the heat dissipation coating layer is a layer formed by using:

a composition containing at least one kind of orthorhombic silicate selected from cordierite and mullite, a fluorine compound and a curing agent; or

a composition containing at least one kind of orthorhombic silicate selected from cordierite and mullite, an acrylic compound and a curing agent (in which at least one of the acrylic compound and the curing agent is silicone-modified).

Item 14. An electronic device, including the radiator according to any one of items 1 to 13.

Item 15. An illumination device, including the radiator according to any one of items 1 to 13.

Item 16. A method of manufacturing the radiator according to any one of items 1 to 13, including the following steps 1 and 2:

step 1: a step of forming two or more laminates including metal foil, a graphite sheet and metal foil in that order; and

step 2: a step of arranging respective laminates obtained in step 1 in a predetermined shape, and then joining part of adjacent laminates by using an adhesive tape, an adhesive, grease or cream solder, and then folding the laminate in the obtained join material in a place in which the laminate is not joined to form a part in which the respective laminates are not brought into contact with each other; or

a step of folding part of the respective laminates obtained in step 1 so as to have a join surface joined with the adjacent laminates, and a part not in contact with the adjacent laminates to each other, and then joining the join surface by using an adhesive tape, an adhesive, grease or cream solder.

### Advantageous Effects of Invention

A radiator (hereinafter also referred to as “present radiator”) according to an embodiment of the invention has difficulty in producing graphite powder, has sufficient strength, and is lightweight and excellent in a heat dissipation effect.

### BRIEF DESCRIPTION OF DRAWINGS

FIG. 1 is a schematic perspective view showing one example of a radiator of the invention.

FIG. 2 is a schematic perspective view showing one example of a radiator of the invention.

FIG. 3 is a schematic perspective view showing one example of a radiator of the invention.

FIG. 4 is a schematic perspective view showing one example of a radiator of the invention.

FIG. 5 is a schematic perspective view showing one example of a radiator of the invention.

FIG. 6 is a schematic perspective view showing one example of a radiator of the invention.

FIG. 7 is a schematic perspective view showing one example of a radiator of the invention.

FIG. 8 is a schematic perspective view showing one example of a radiator of the invention.

FIG. 9 is a schematic perspective view showing one example of a radiator of the invention.

FIG. 10 is a schematic perspective view showing one example of a radiator of the invention.

FIG. 11 is a schematic perspective view showing one example of a radiator of the invention.

FIG. 12 is a schematic perspective view showing one example of a radiator of the invention.

FIG. 13 is a schematic perspective view showing one example of a radiator of the invention.

FIG. 14 is a schematic perspective view showing one example of a radiator of the invention.

FIG. 15 is a schematic perspective view showing one example of a radiator of the invention.

FIG. 16 is a schematic perspective view showing one example of a radiator of the invention.

FIG. 17 is a schematic perspective view showing one example of a radiator of the invention.

FIG. 18 is a schematic perspective view showing one example of a radiator of the invention.

FIG. 19 is a schematic perspective view showing one example of a radiator of the invention.

FIG. 20 is a schematic perspective view showing one example of a radiator of the invention.

FIG. 21 is a schematic perspective view showing one example of a radiator of the invention.

FIG. 22 is a schematic perspective view showing one example of a radiator of the invention.

FIG. 23 is a schematic perspective view showing one example of a radiator of the invention.

FIG. 24 is a schematic perspective view showing one example of a radiator of the invention.

FIG. 25 is a schematic perspective view showing one example of a radiator of the invention.

FIG. 26 is a schematic perspective view showing one example of a radiator of the invention.

FIG. 27 is a schematic perspective view showing one example of a radiator of the invention.

FIG. 28 is a schematic perspective view showing one example of a radiator of the invention.

FIG. 29 is a schematic perspective view showing one example of a radiator of the invention.

FIG. 30 is a schematic perspective view showing one example of a radiator of the invention.

FIG. 31 is a schematic perspective view showing one example of a radiator of the invention.

FIG. 32 is a schematic perspective view showing one example of a radiator of the invention.

FIG. 33 is a schematic perspective view showing one example of a radiator of the invention.

FIG. 34 is a schematic perspective view showing one example of a radiator of the invention.

FIG. 35 is a schematic perspective view showing one example of a radiator of the invention.

FIG. 36 is a schematic front view showing one example of a use mode of a radiator of the invention.

FIG. 37 is a schematic explanatory view (front view) in providing a join layer on a laminate in Example 1.

FIG. 38 is a schematic front view showing a join body formed in Example 1.

FIG. 39 (a) is a schematic front view of a heat sink obtained in Comparative Example 7, and FIG. 39 (b) is a schematic plan view of the heat sink.

### DESCRIPTION OF EMBODIMENTS

### Radiator

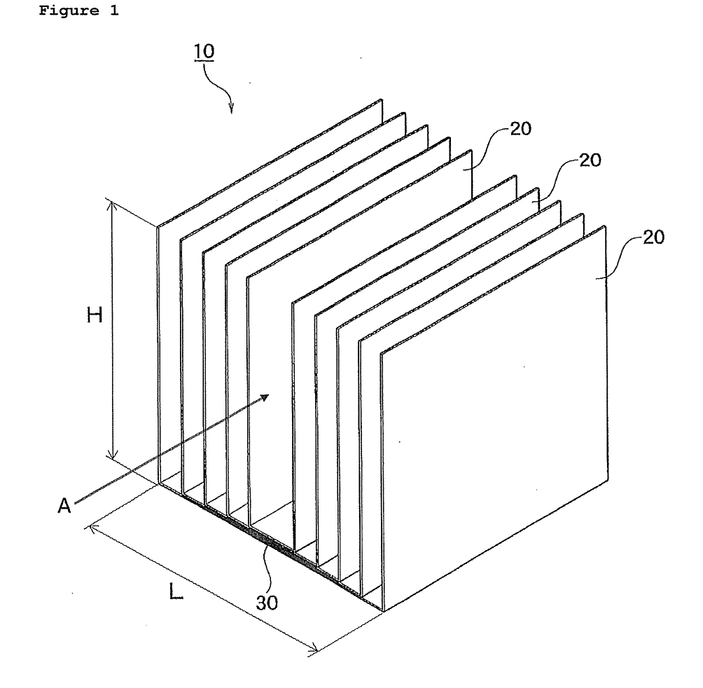

An embodiment of the invention will be described below based on FIG. 1.

Radiator 10 according to the embodiment of the invention has two or more heat dissipation fins,

the heat dissipation fins each are a laminate including metal foil, a graphite sheet and metal foil in that order,

all the heat dissipation fins included in the radiator each have a join surface (hereinafter, also referred to simply as “join surface”) 30 joined with adjacent heat dissipation fins, and a non-contact part not in contact with the adjacent heat dissipation fins, and

at least two of the heat dissipation fins each included in the radiator has blade portion 20 having a predetermined angle with respect to the join surface in at least part of the non-contact part.

Such a radiator suppresses scattering and falling of powder due to brittleness derived from a layer structure of graphite while taking advantage of excellent thermal conductivity of the graphite sheet, and is lightweight and excellent in heat dissipation efficiency. In particular, in the present radiator, heat generated in a heating unit can be transferred to the metal foil covering both surfaces of the graphite sheet. Further, the graphite sheet has significantly high thermal conductivity in the in-plane direction, and therefore the heat from the heating unit can be uniformly dissipated wholly on a surface of the blade portion, and the present radiator is considered to be excellent in a heat dissipation effect. Moreover, the graphite sheet as a single body has high flexibility and difficulty in retaining a shape. However, according to the embodiment of the invention, even if the graphite sheet is used, the radiator having a desired shape can be formed.

Moreover, the present radiator particularly has two or more heat dissipation fins and the blade portions formed of at least two of the heat dissipation fins, and therefore the present radiator is particularly excellent in the heat dissipation efficiency, and even if a thin laminate is used in view of achievement of lightweight or the like, the present radiator is formed into the radiator having high strength. In particular, even when the radiator is fixed to the heating unit by using screw clamp or lapped flat seam or the like and the resulting assembly is used, the radiator has sufficient strength.

In the embodiment of the invention, a term “non-contact part” means a part in which any part in one heat dissipation fin is not brought into contact with any other heat dissipation fin, and specific examples of such a non-contact part include blade portion 20 rising from join surface 30 in FIG. 1, and when FIG. 1 is viewed from a direction of A, an upper surface of join surface 30 is not the non-contact part.

A shape of the present radiator is not particularly limited as long as the advantageous effects of the invention are not adversely affected, and only needs to be appropriately selected according to a desired application, for example, a shape of the heating unit, a place in which the radiator is used, and so forth. In the present radiator, the shape can be appropriately changed according to a situation, and can also be fixed to a desired shape in several cases.

The present radiator has blade portion 20 having a predetermined angle with respect to the join surface, and blade portion 20 included in the radiator is formed of at least two of the heat dissipation fins. More specifically, the present radiator is different from a radiator having a blade portion formed of one heat dissipation fin as shown in FIG. 39.

The angle is not particularly limited, but in consideration of capability of obtaining a radiator excellent in the heat dissipation efficiency, and suppressing graphite sheet break or graphite powder dropping in folding the laminate, or the like, the angle is preferably 30 to 150 degrees, and further preferably 45 to 135 degrees.

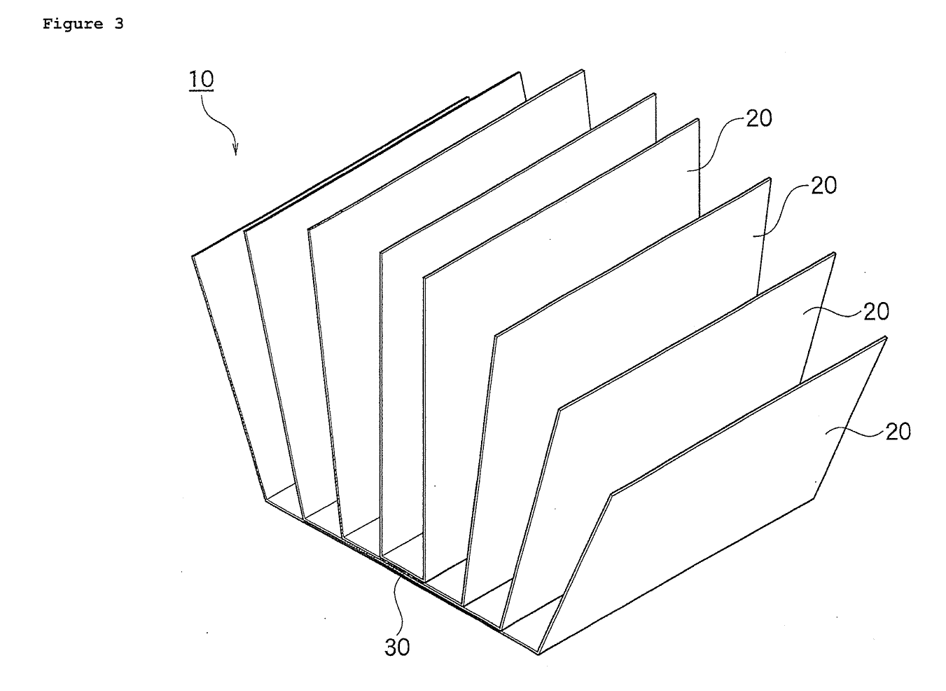

The angle of the blade portion may be substantially identical or different among all the heat dissipation fins each having the blade portion included in the radiator. In the latter case, the angle is preferably increased accordingly toward an outside of the radiator (example: FIG. 3) in view of capability of obtaining a radiator excellent in the heat dissipation efficiency, and so forth.

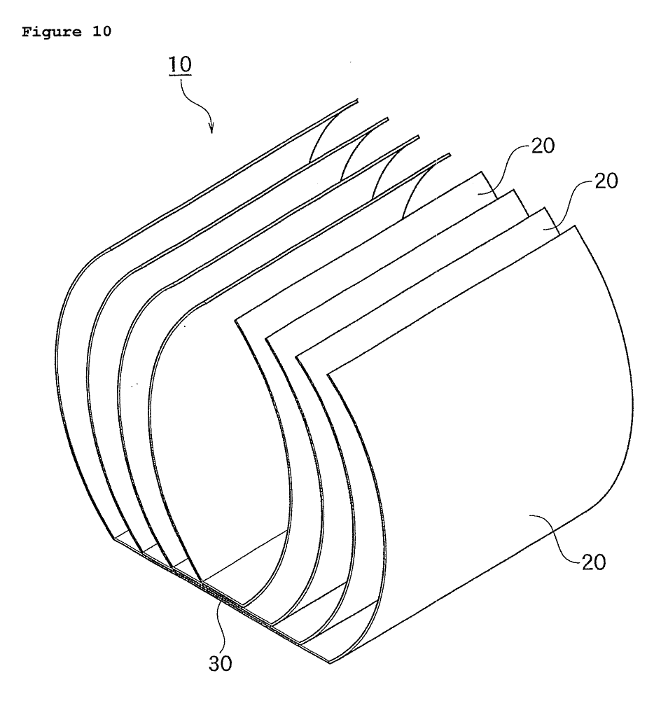

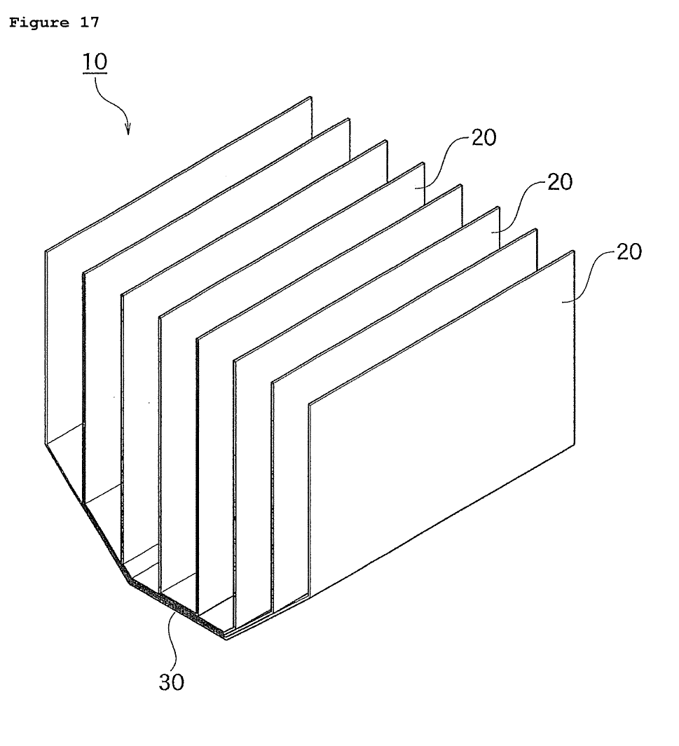

For example, the radiator in FIG. 1 has blade portion 20 having an angle of about 90 degrees with regard to join surface 30, and in the radiator in FIG. 3, blade portion 20 on a rightmost side when viewed from the same direction as A in FIG. 1 has an angle of about 105 degrees with regard to join surface 30, and a radiator in FIG. 10 has blade portion 20 having an angle of about 135 degrees with regard to join surface 30, and all blade portions 20 included in a radiator in FIG. 18 each have an angle of about 90 degrees with regard to join surface 30.

A term “predetermined angle” means an angle more than 0 degrees and less than 180 degrees.

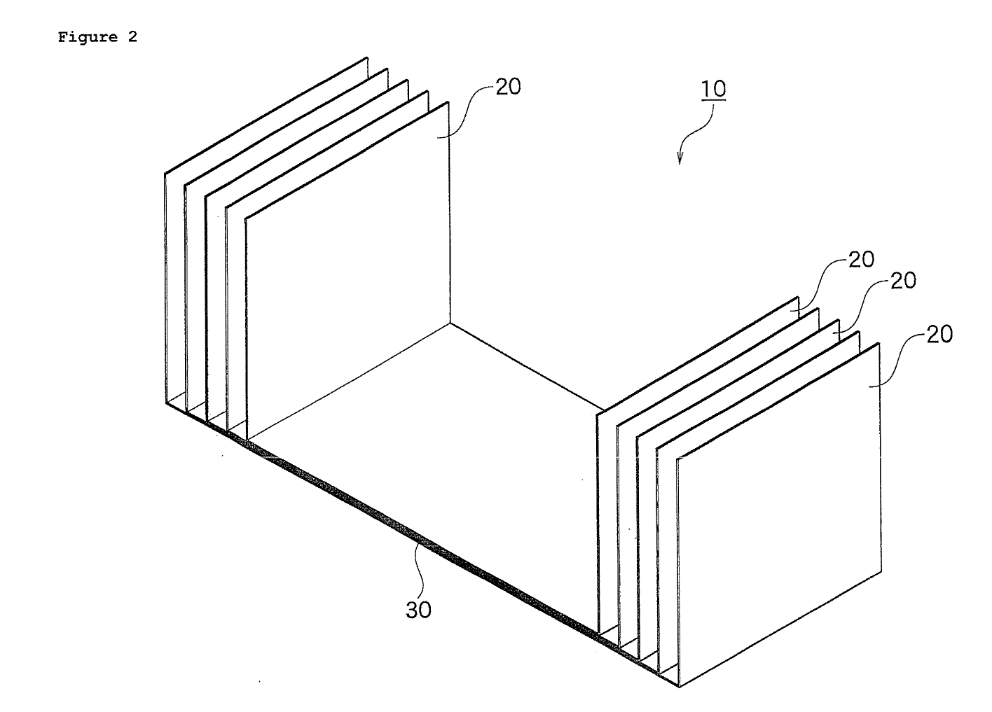

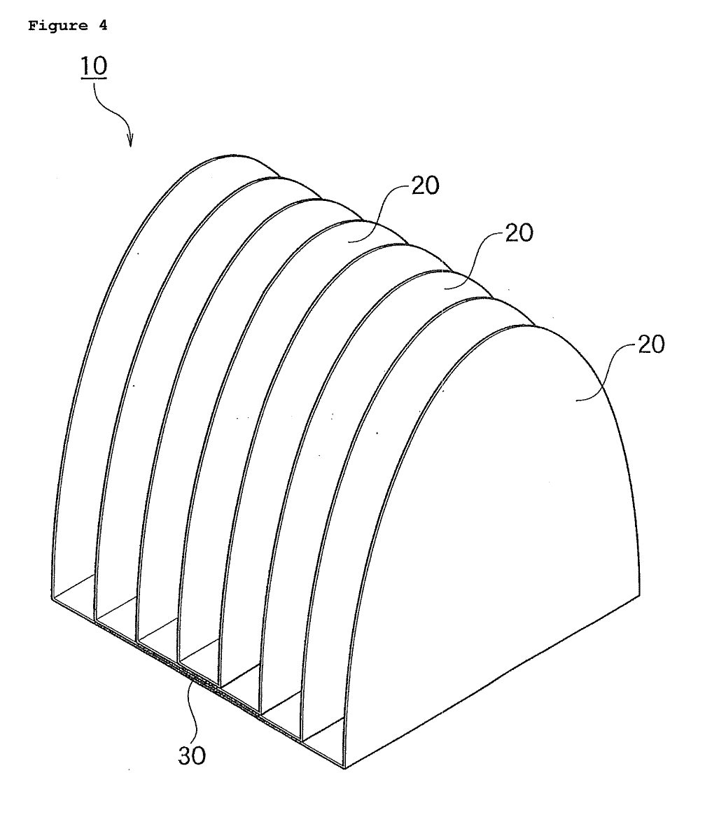

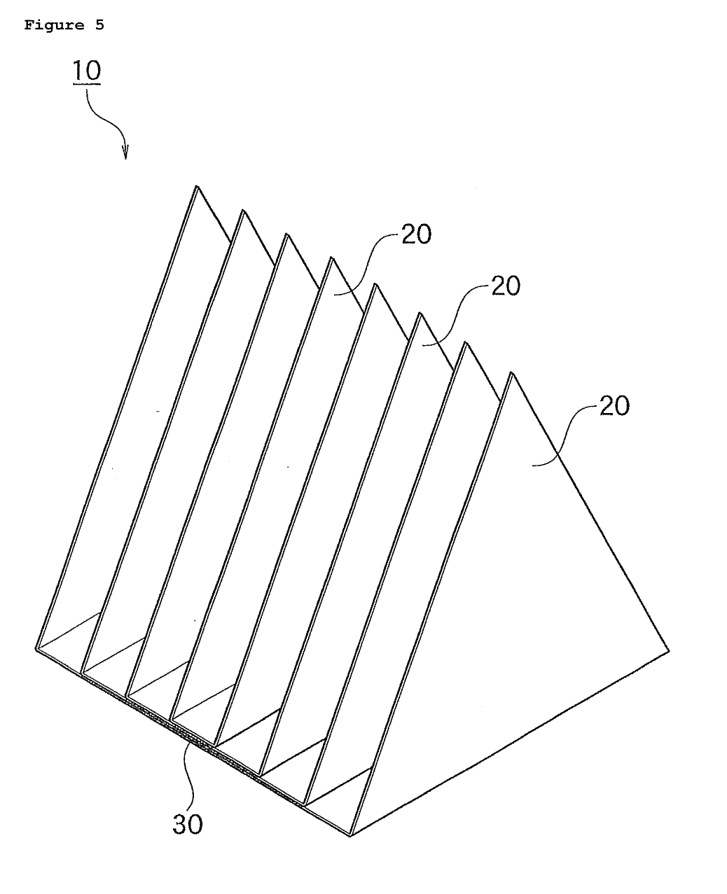

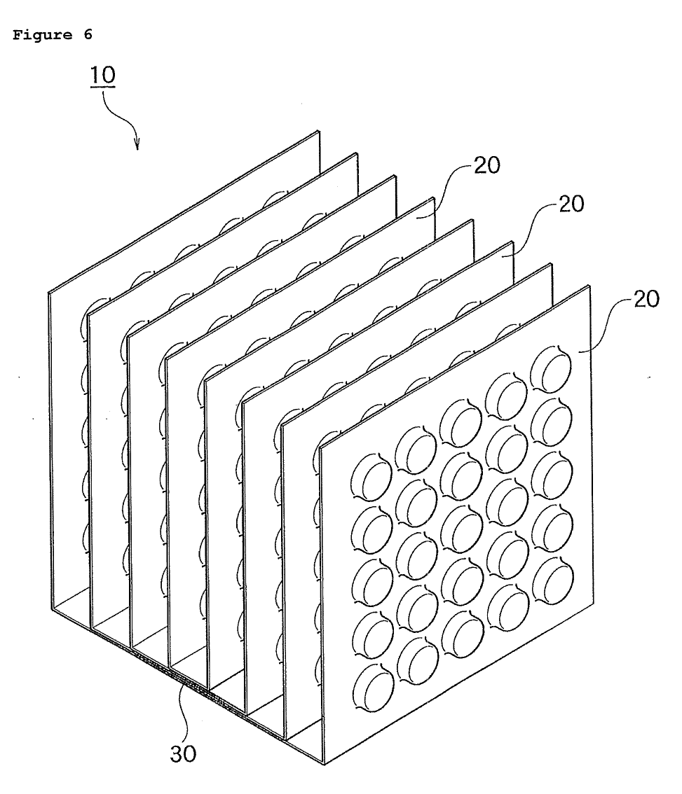

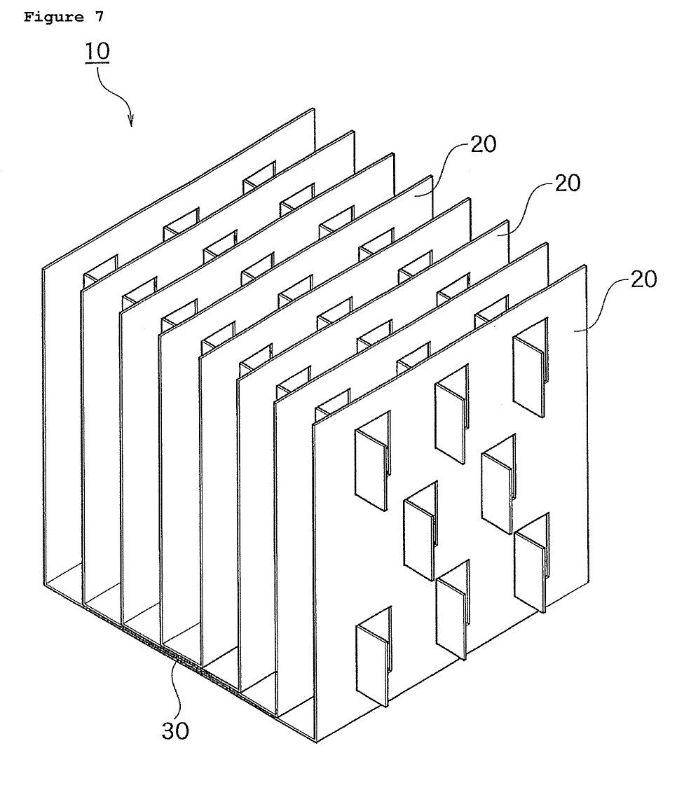

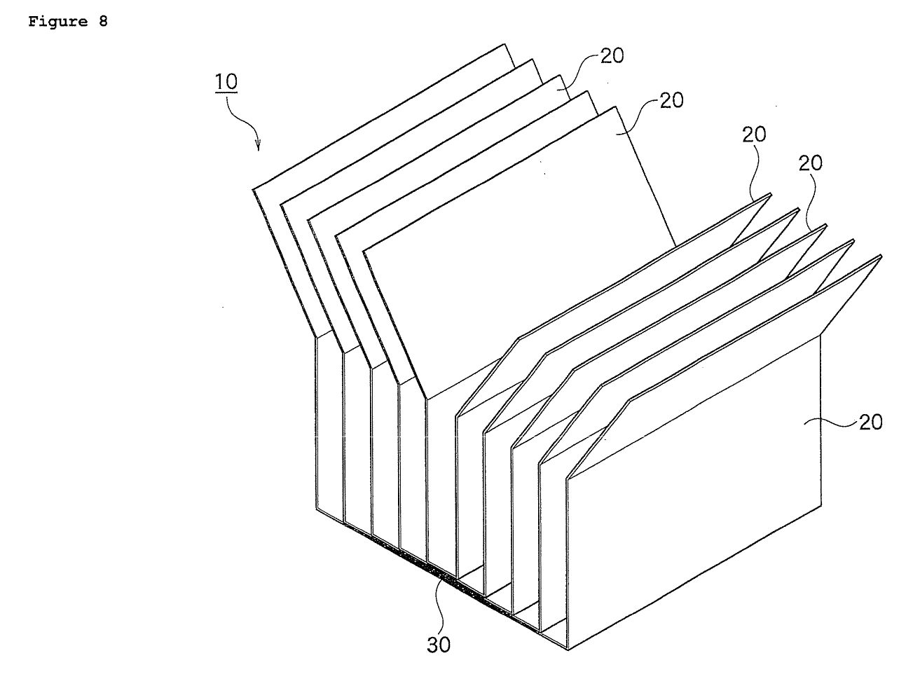

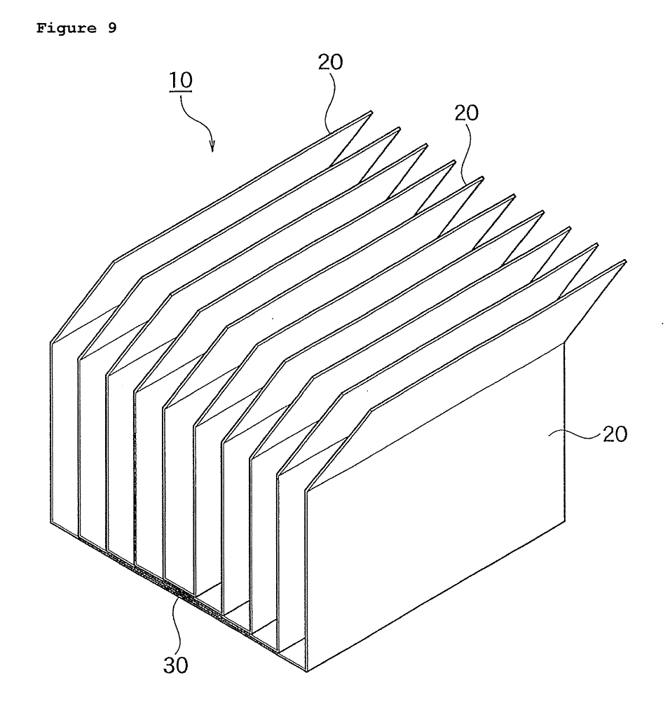

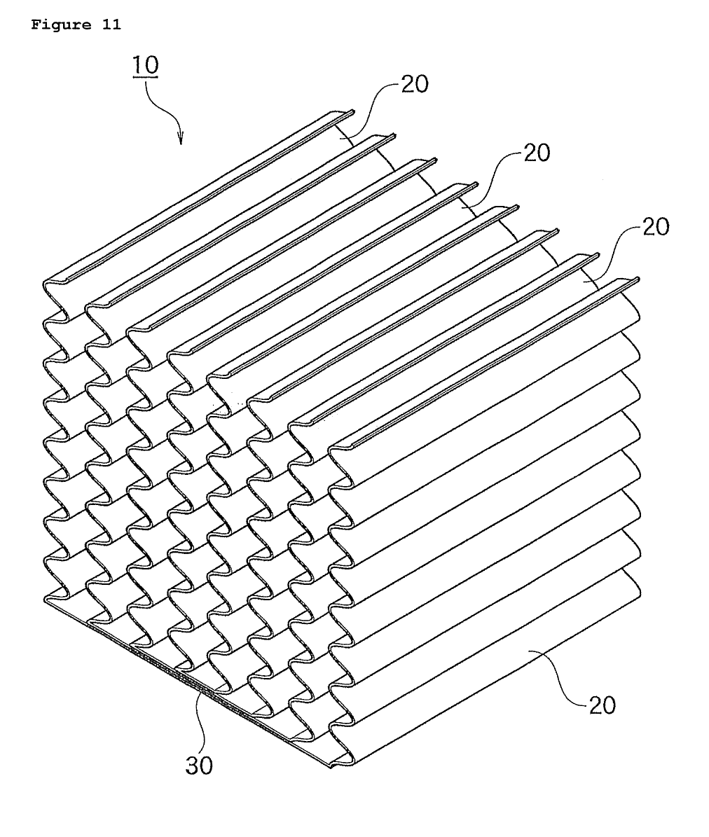

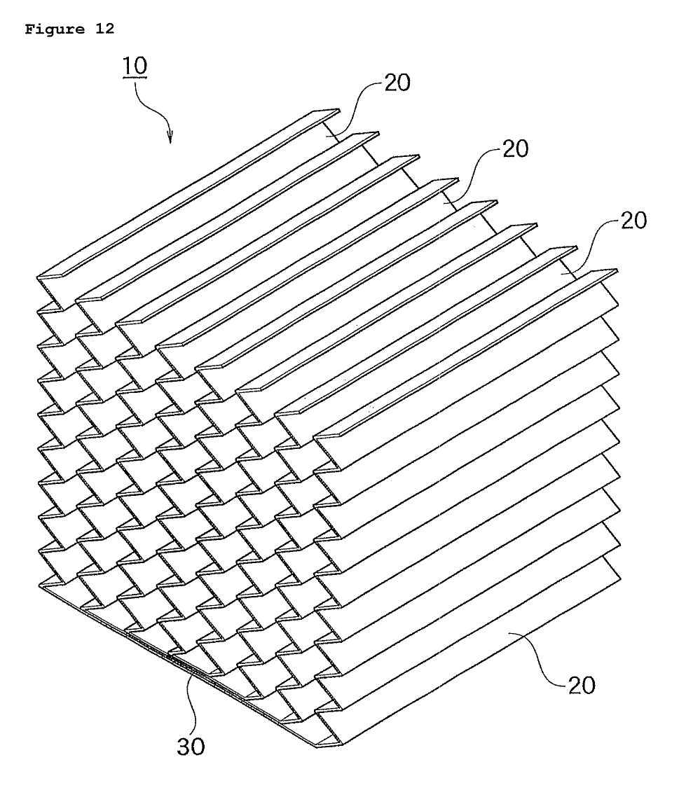

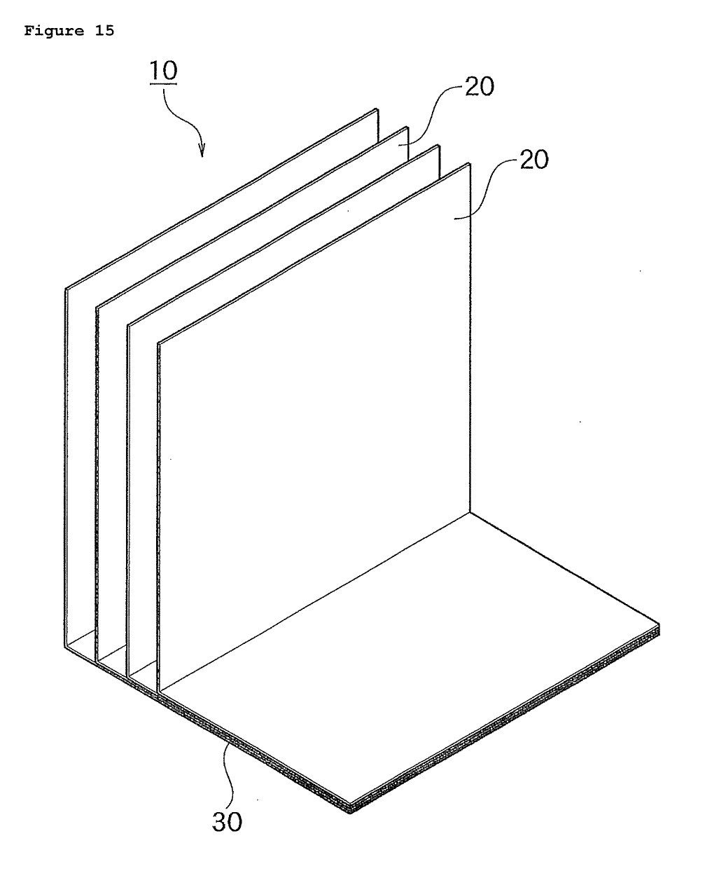

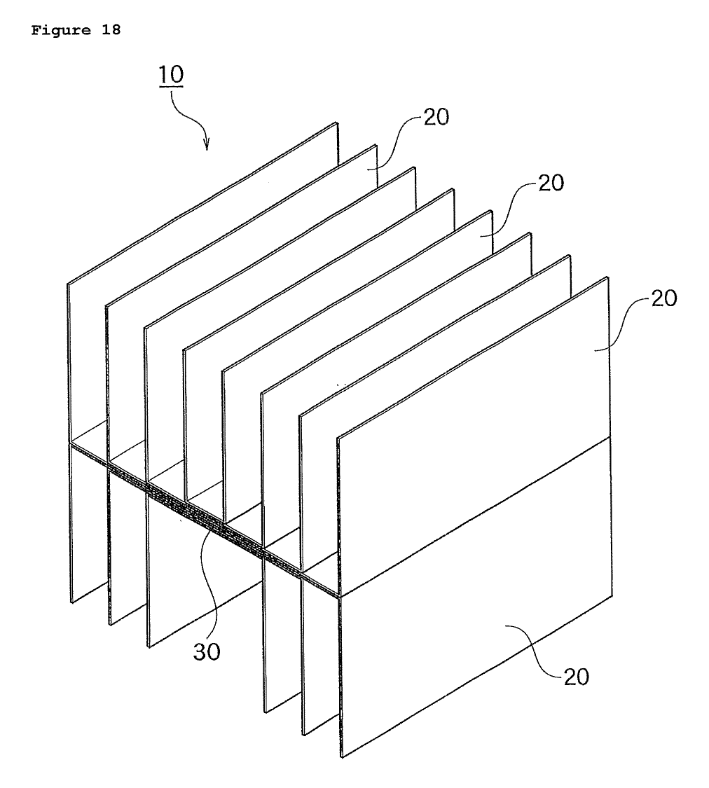

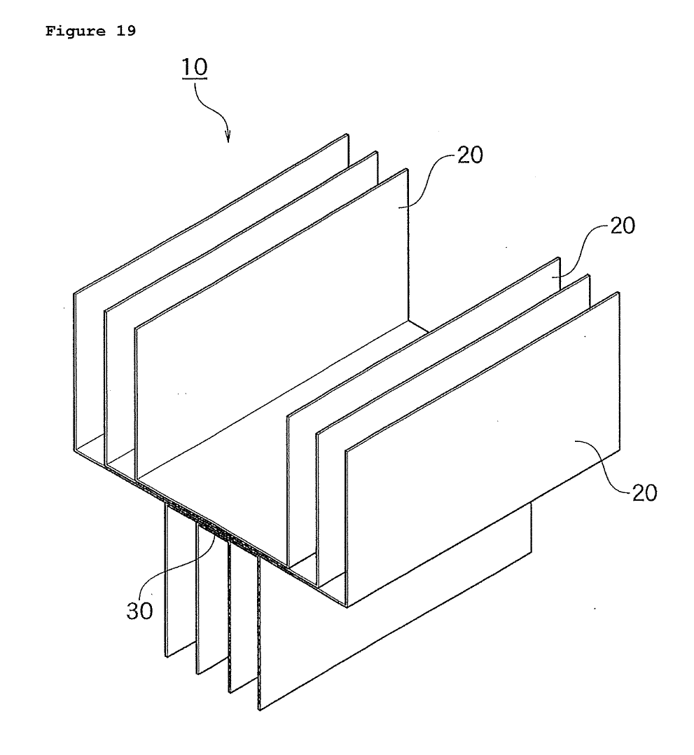

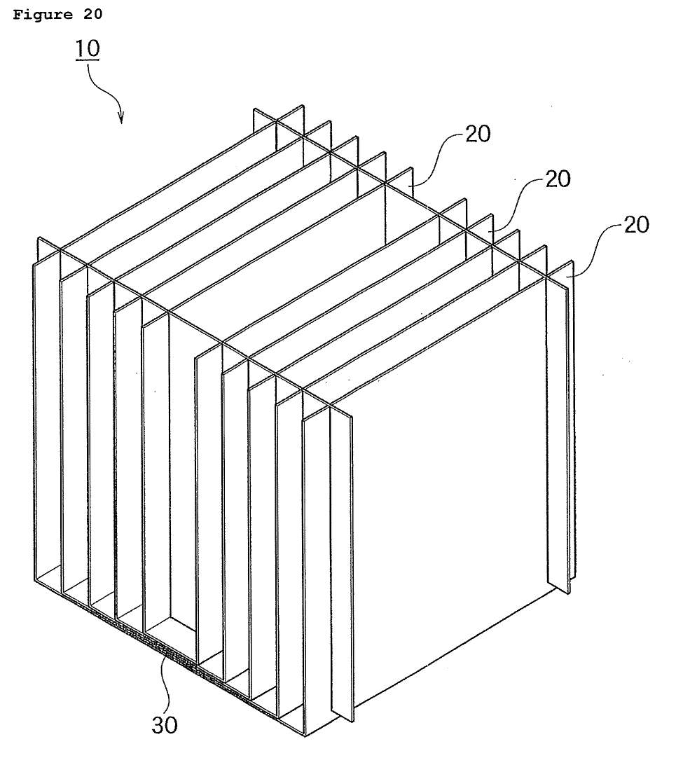

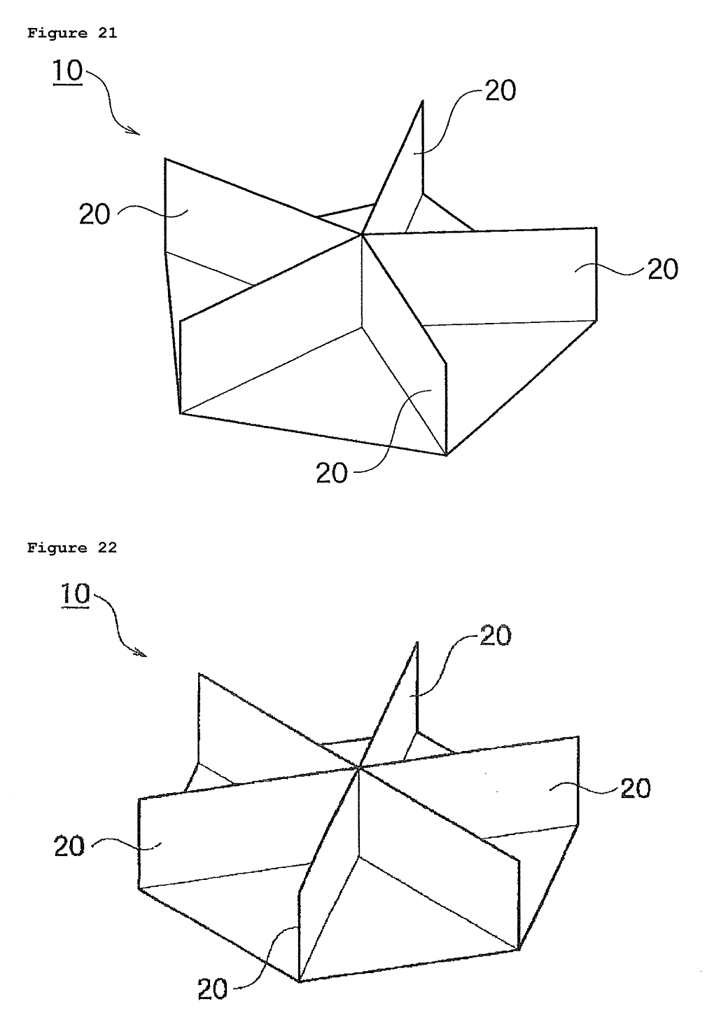

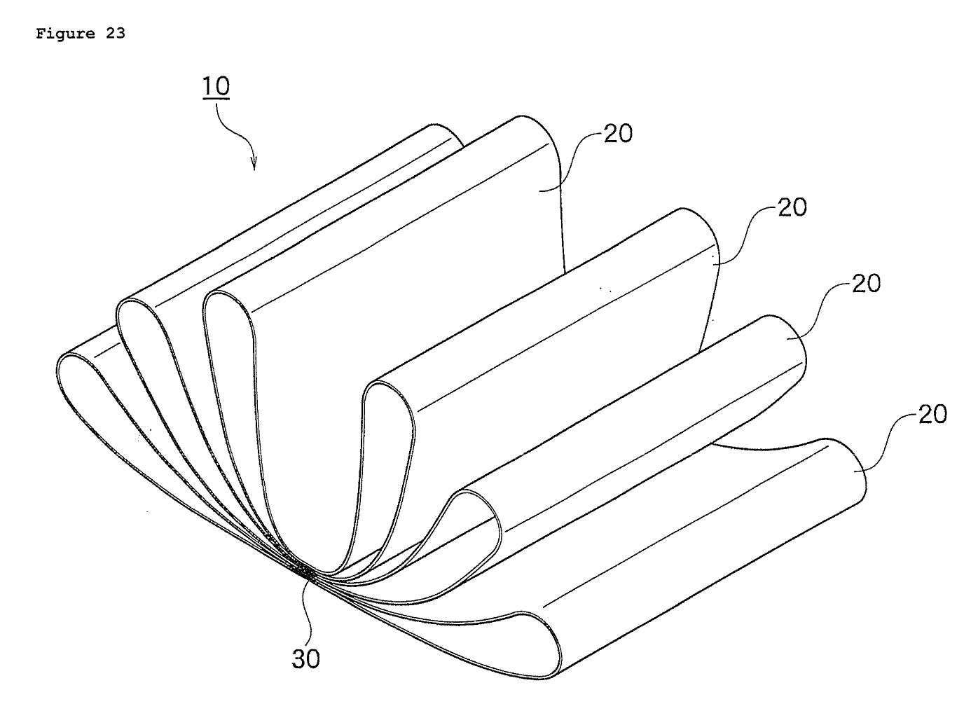

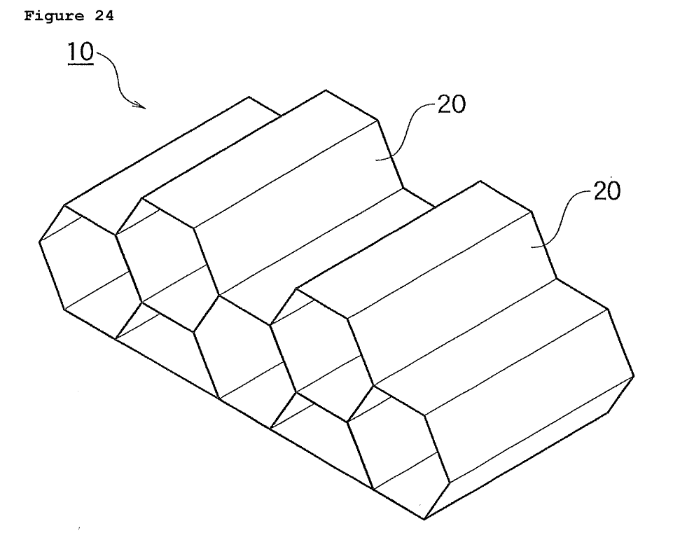

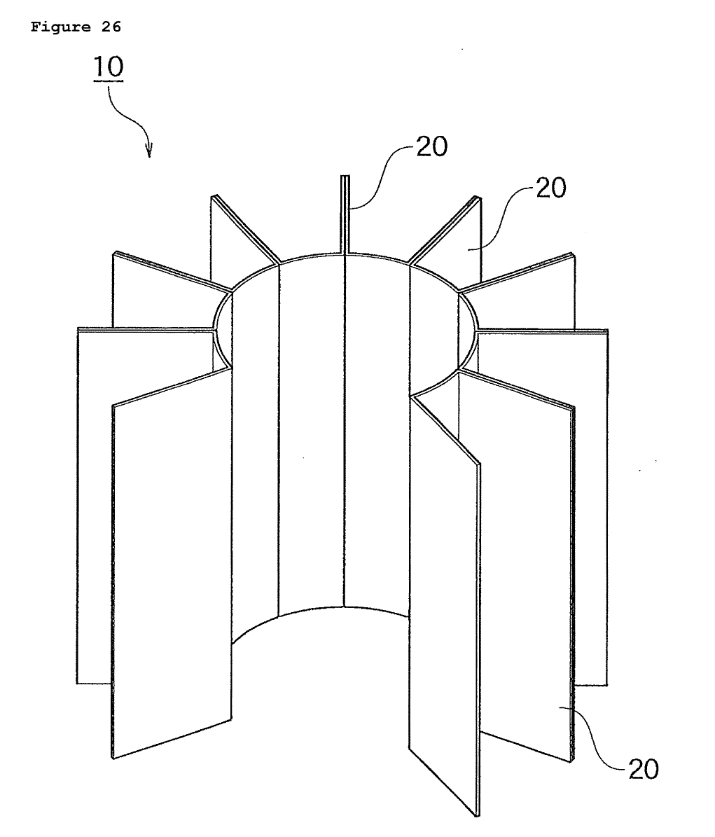

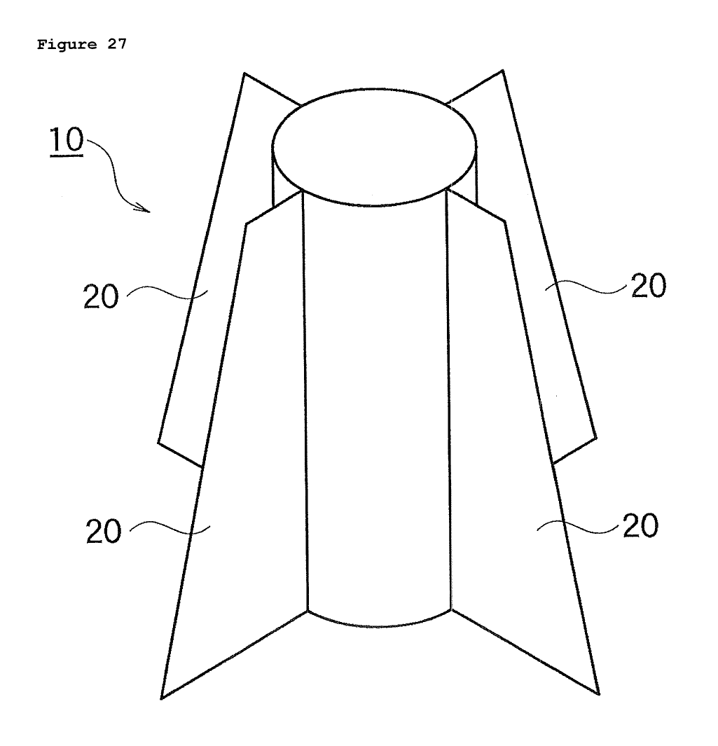

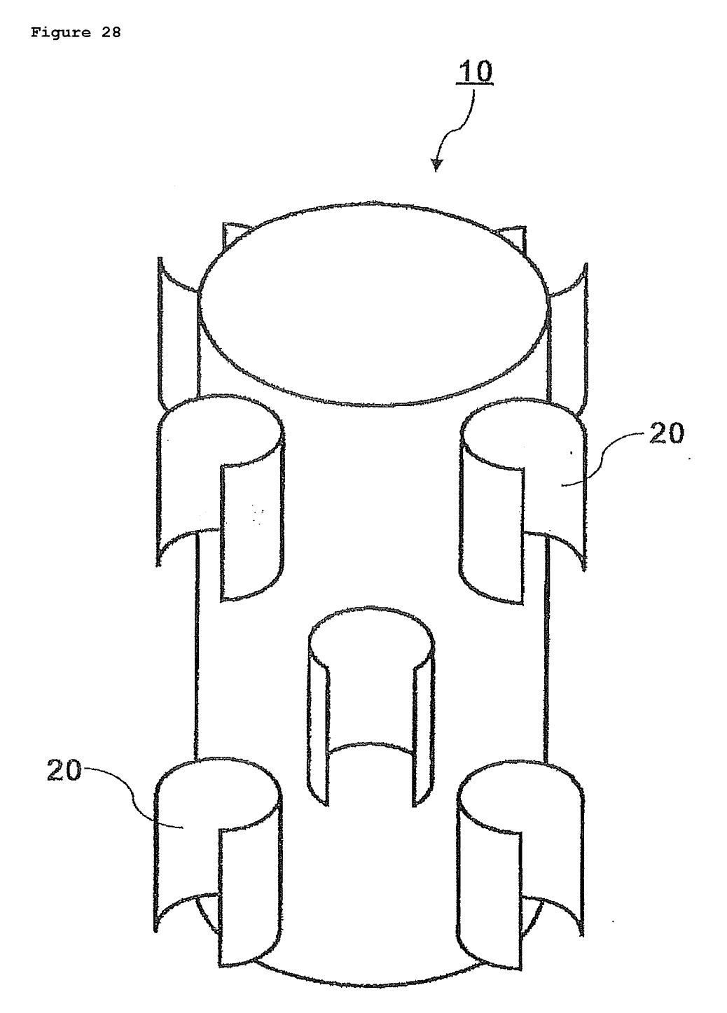

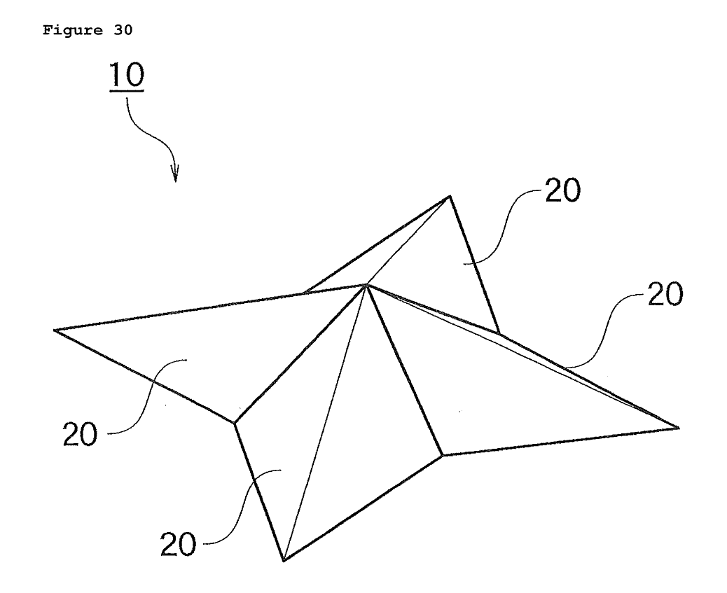

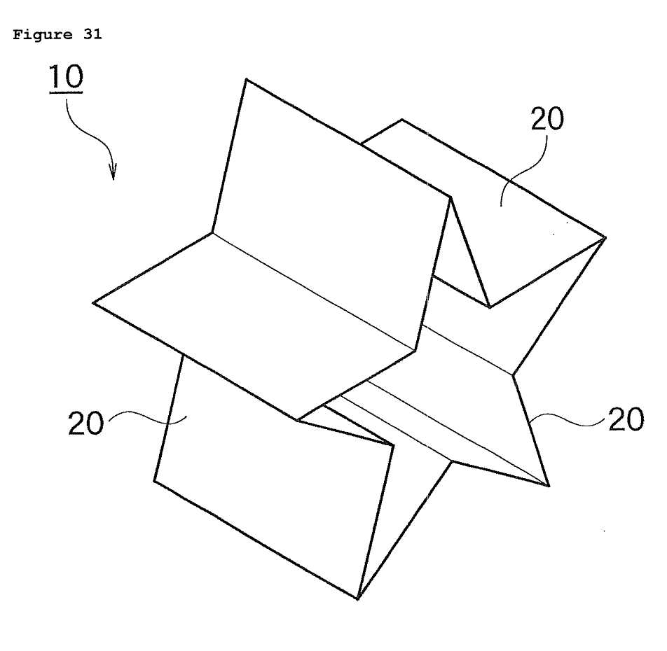

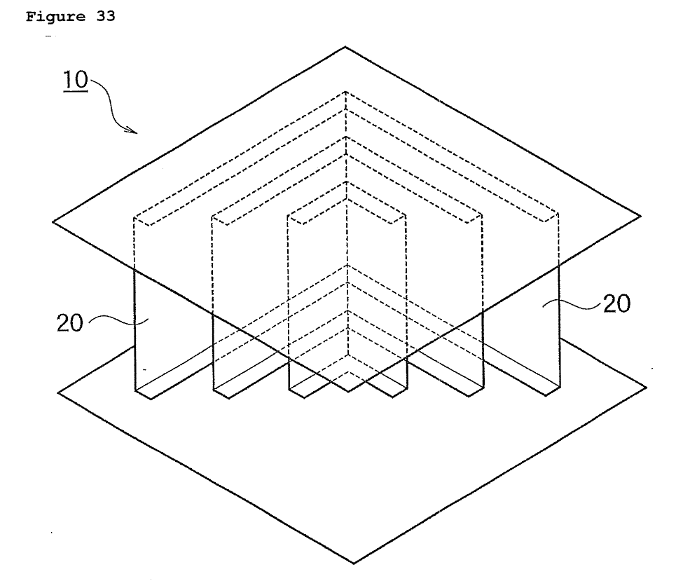

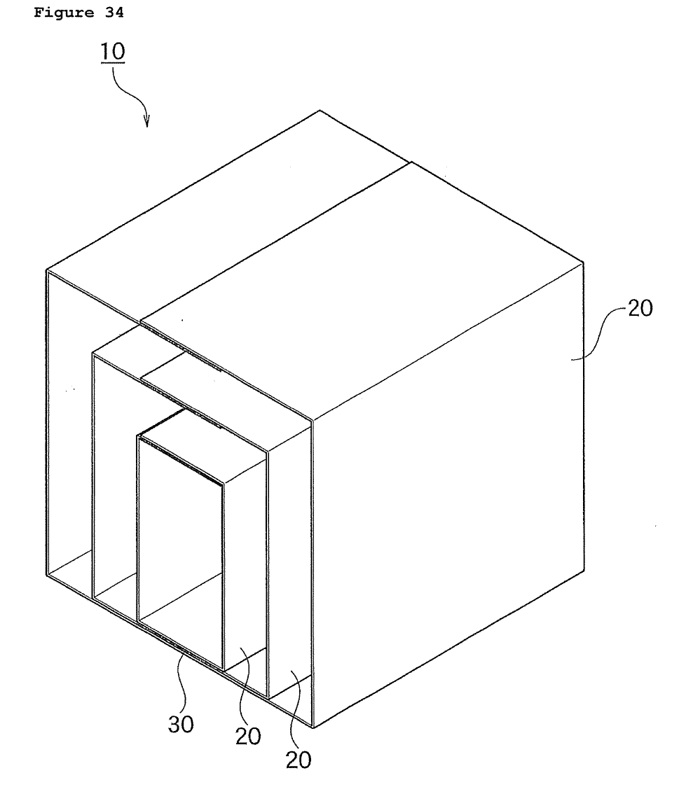

Specific examples of the shape of the present radiator include shapes described in FIGS. 1 to 35. In addition to the shapes described in the Figures, specific examples thereof include a radiator in which the number of heat dissipation fins to be used is changed, a radiator in which intervals between respective blade portions are various (examples: a radiator in which an interval between the blade portions is substantially uniform, a radiator in which an interval between the blade portions is large in only a center portion of the radiator, a radiator in which an interval between the blade portions increases accordingly toward an outside of the radiator, a radiator in which an interval between the blade portions is dispersed), and a radiator in which a shape of the blade portion is changed (example: a radiator in which a shape of the blade portion in the radiator described in FIGS. 2, 3, 15 to 22 or the like changes to a shape as described in FIGS. 4 to 12).

Moreover, in order to retain the radiator in a desired shape, the present radiator may have a fixing means for fixing the blade portion.

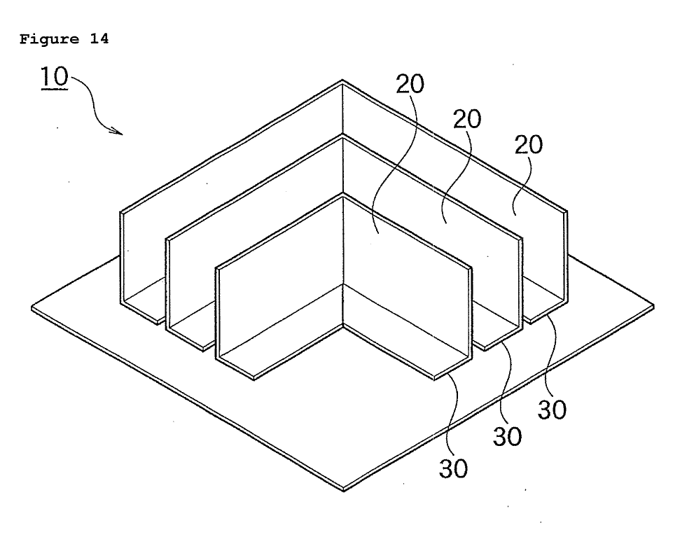

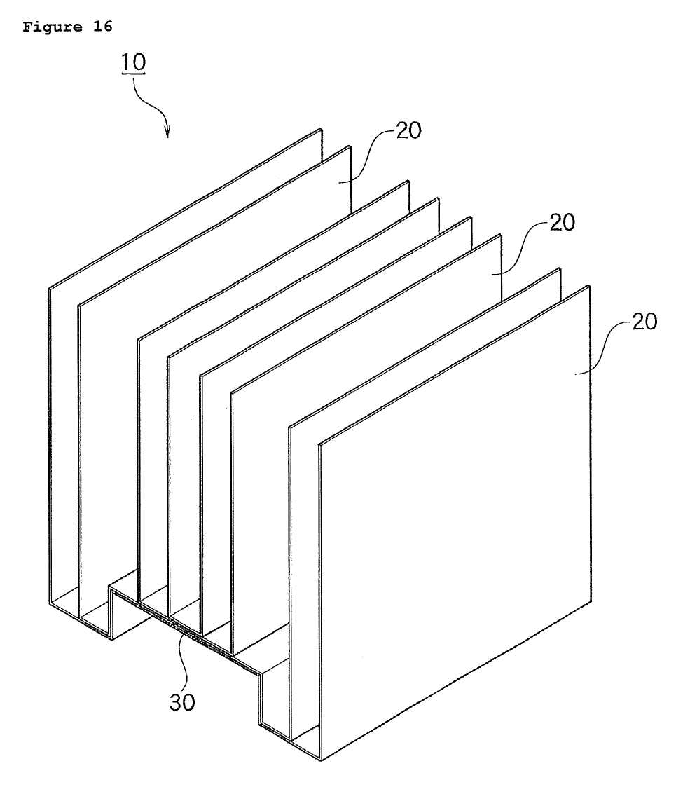

As the shape of the present radiator, when viewed from the same direction as A in FIG. 1 (in the invention, the case is also referred to as “when the state of folding the heat dissipation fin is viewed from the front,” and the figure in the case is also referred to as “front view”), the shape is preferably a shape having a substantially L shape (example: FIG. 15), a substantially U shape (example: FIG. 17), a substantially concave shape (channel shape, examples: FIGS. 1, 2, and 4 to 6) or a substantially fan shape (example: FIG. 3). The radiator each having such a shape is preferred because the radiator has a satisfactory heat dissipation effect.

The present radiator preferably has a shape according to which ventilation resistance of air passing through the blade portion is reduced, and air flow is not inhibited. From the view described above, the radiators having the shapes about shown in diagrams 1 to 12, 15 to 19, 21, 22 and so forth are preferred.

Moreover, the present radiator is preferably the radiator having the shape about shown in diagrams 33 to 35 and so forth each in view of, for example, capability of obtaining a radiator being excellent in heat dissipation characteristics, even with lightweight, particularly excellent in rigidity.

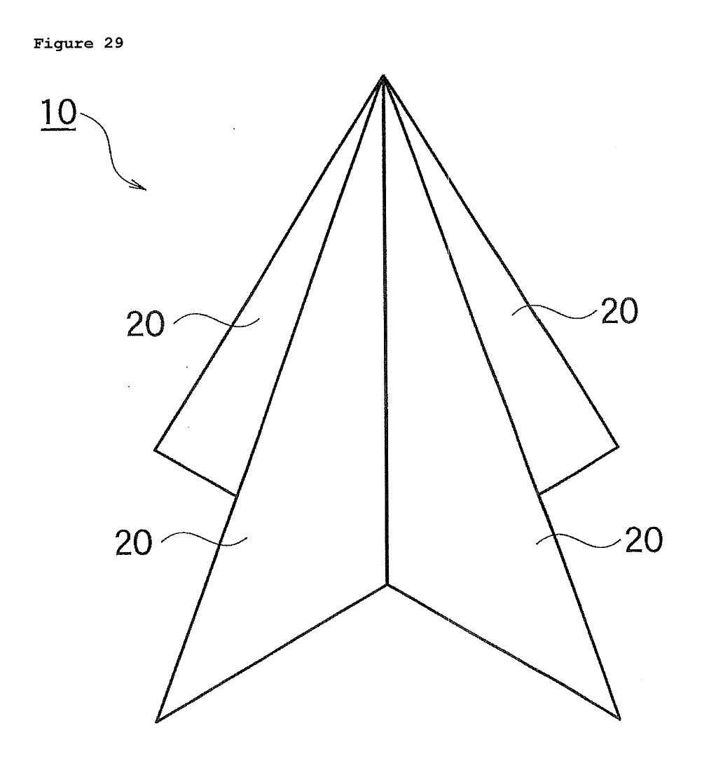

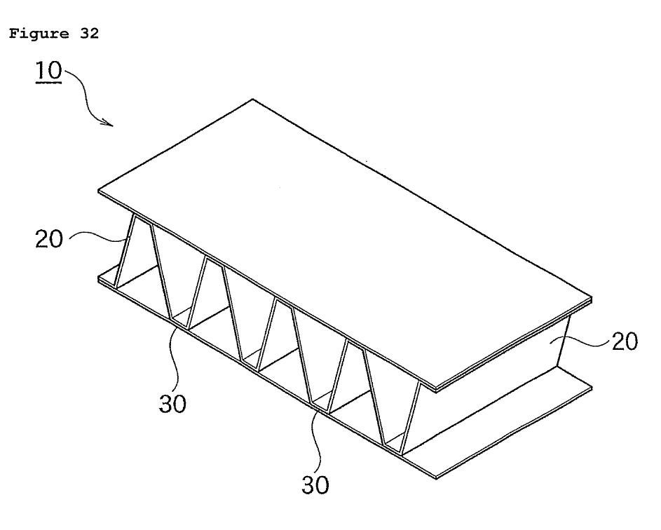

In addition, the radiators in FIGS. 29 to 32 each have two or more heat dissipation fins, in which blade portion 20 is composed of at least two of the heat dissipation fins, although not clear in the drawings. For example, in the radiator in FIG. 32, blade portion 20 forming an intermediate layer thereof only needs to be formed of two or more heat dissipation fins, and the blade portion 20 is formed of two of the heat dissipation fins, four heat dissipation fins or nine heat dissipation fins, for example.

In the invention, a term “adjacent heat dissipation fins” is used in the meaning in which, when a certain heat dissipation fin X and a certain heat dissipation fin Y are joined, the heat dissipation fins X and Y are referred to as the adjacent heat dissipation fins.

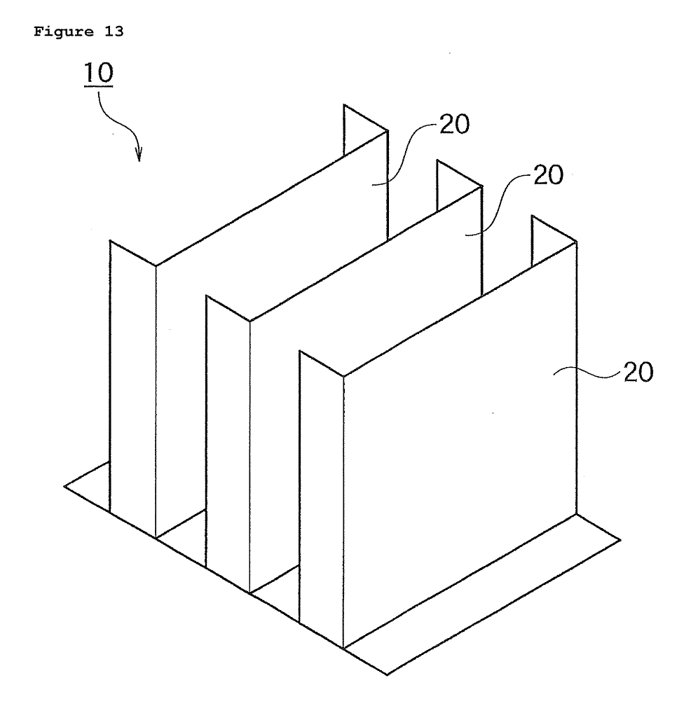

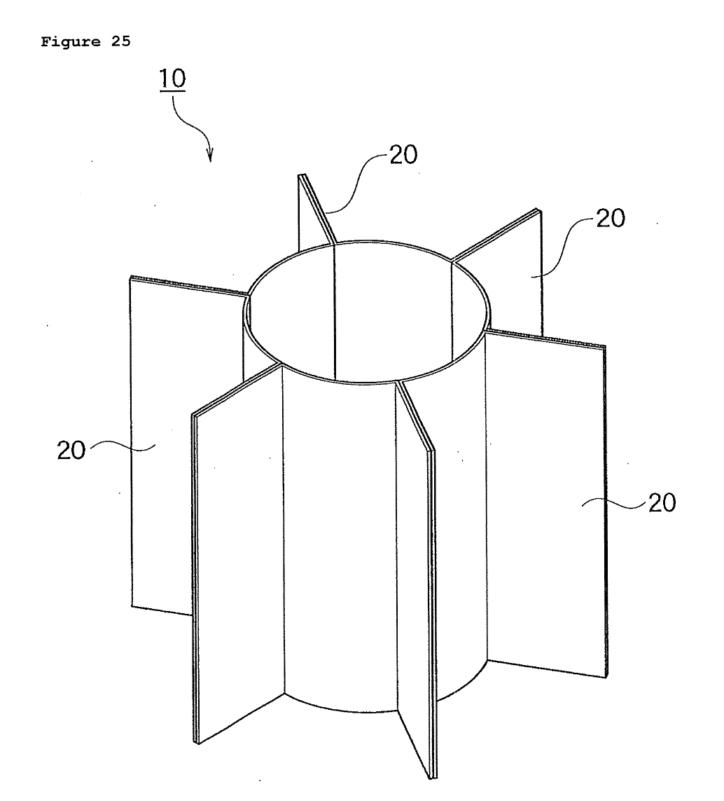

For example, a heat dissipation fin forming a blade portion on a rightmost side, and a heat dissipation fin forming a blade portion in one on the left side when the radiator in FIG. 1 is viewed from the direction of A are the adjacent heat dissipation fins. A heat dissipation fin forming a blade portion, and a heat dissipation fin forming a bottom surface when the radiator in FIG. 13, 14 or the like is viewed from a direction similar to the direction of A in FIG. 1 are the adjacent heat dissipation fins. In FIG. 25 or the like, a substantially cylindrical heat dissipation fin, and a heat dissipation fin forming blade portion 20 are the adjacent heat dissipation fins.

In order to further enhance the heat dissipation effect of the radiator in the embodiment of the invention, an area of the non-contact part is preferably increased as much as possible, an area of the blade portion is further preferably increased as much as possible, the area of the non-contact part is still further preferably increased to a level larger than the area of the join surface, and the area of the non-contact part is particularly preferably increased by twice or more the area of the join surface. In order to efficiently dissipate heat particularly in a narrow installation area, the heat dissipation fin is preferably processed into a three-dimensional shape to increase a surface area.

In addition, an expression “area of the join surface” means an area of apart serving as the join surface of a largest surface (one surface) of the laminate forming the heat dissipating fin, and an expression “area of the non-contact part” means an area other than the part serving as the join surface of the one surface.

The present radiator is ordinarily used in contact with the heating unit. In the above case, the metal foil having no anisotropy in thermal conduction preferably exists in the part of the radiator in contact with the heating unit in order to transfer the heat generated in the heating unit to the radiator as a whole.

Then, the heat once transferred to the radiator is diffused wholly into the radiator by high heat conduction characteristics of the graphite sheet in the in-plane direction, and further transferred to the metal foil on a side of the graphite sheet opposite to the heating unit to develop high heat dissipating performance.

More specifically, the present radiator has high heat dissipation characteristics by including two or more laminates described above. The present inventors have diligently continued to conduct study, and as a result, the present inventors have found that, in order to further improve the heat dissipation efficiency of the radiator using such a laminate, a ratio (H/L) is preferably 1.0 or more, and further preferably 1.5 or more, in terms of the ratio (H/L): a ratio of a maximum length H of the radiator in a substantially vertical direction (maximum length in a longitudinal direction when viewed from the direction of A in FIG. 1 (also referred to simply as “a length in the longitudinal direction”)) to a maximum length L thereof in a direction substantially horizontal to the join surface (maximum length in a transverse direction when viewed from the direction similar to A in FIG. 1 (hereinafter, referred to simply as “length in the transverse direction”). In addition, an upper limit of H/L is preferably 2.5 in view of weight, strength or the like of the radiator.

More specifically, the present radiator uses the laminate, which is different from existing radiators, and therefore the heat is preferably diffused in the longitudinal direction to suppress a temperature rise of the heating unit.

On the other hand, in the existing radiators, the length in the transverse direction has been ordinarily longer than the length in the longitudinal direction. The reason is considered that, in the existing radiators, the heat is easily transferred in the transverse direction, and therefore the existing radiators have had an aim of improving the heat dissipation characteristics by using the radiator longer in the transverse direction.

As the present radiator, the radiator having H/L satisfying the range described above, and as the shape, having the shape about represented by diagrams 1, 3, 8, 15, 16 and 19 is preferred in view being excellent in the heat dissipation efficiency, even with lightweight and further ease of manufacture and the like. Moreover, in the above case, the shape of the blade portion may be the shapes about as in diagram 11 or 12 in view of capability of obtaining a radiator having superb heat dissipation efficiency and the like, or the shape about as in diagram 13 or 14 in view of capability of obtaining a radiator having superb rigidity and the like.

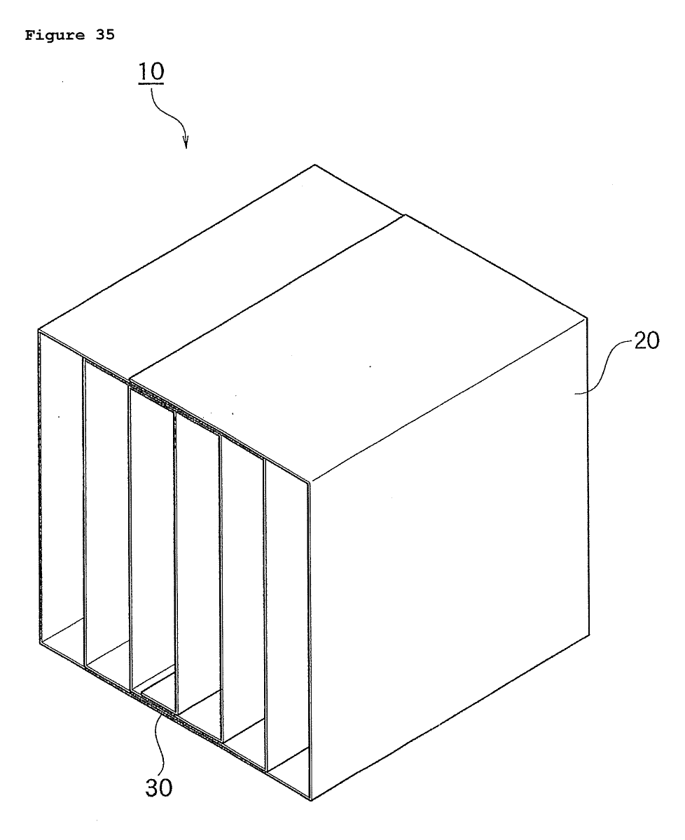

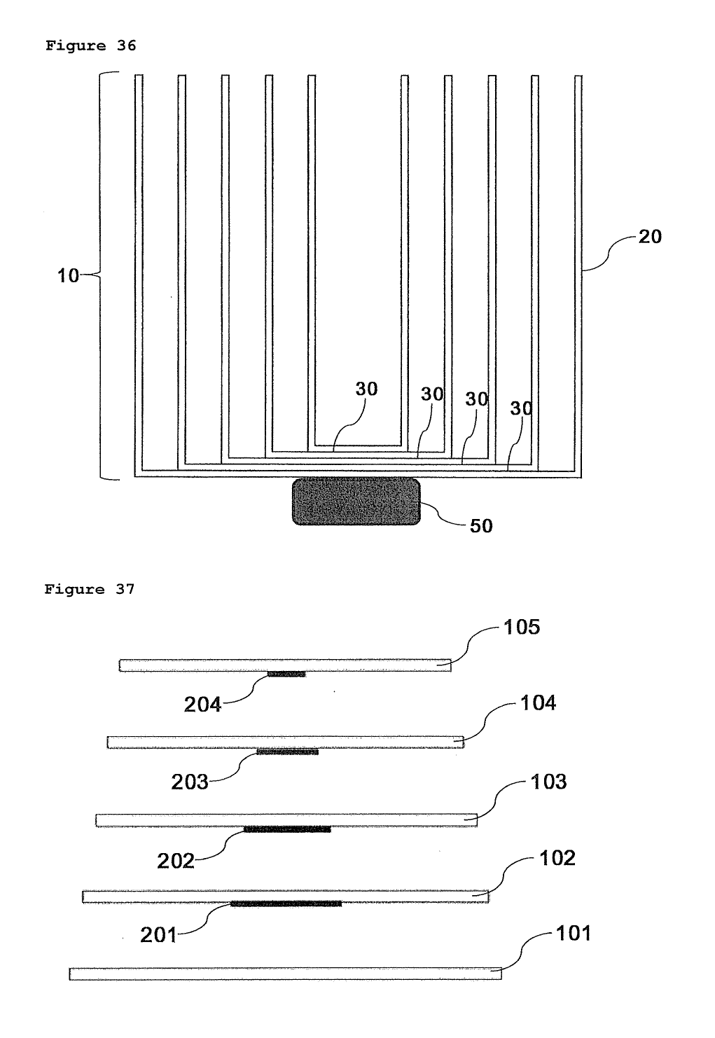

Moreover, when the present radiator is used in contact with the heating unit, for example, when heating unit 50 is brought into contact with a place in a center portion of the join surface 30 and on a side opposite to the side from which the heat dissipation fins rise (see FIG. 36), if the heat dissipation fins rise in apart close to the heating unit (the blade portions exist in the part close to the heating unit), the radiator having superb heat dissipation efficiency is obtained, and such a case is preferred.

More specifically, when the heating unit is brought into contact with the place in the center portion of join surface 30, and on the side opposite to the side from which the heat dissipation fins rise, the radiator having the shape in FIG. 1 is superior in the heat dissipation efficiency to the radiator having the shape in FIG. 2, and therefore is preferred.

The number of the heat dissipation fins used in the present radiator is not particularly limited as long as the number is two or more. If the number of the heat dissipation fins used is increased, a large number of blade portions can be formed and the heat dissipation characteristics tend to be improved. However, if the number of the fins is excessively large, reduction of the heat dissipation characteristics or the like by a join part may be caused, and therefore the number is, for example 2 to 20, preferably 2 to 10, and further preferably 4 to 10.

### Heat Dissipation Fin

The present radiator has two or more heat dissipation fins being laminates including the metal foil, the graphite sheet and the metal foil in that order.

In the embodiment of the invention, such a heat dissipation fin is used, and therefore the radiator being excellent in the heat dissipation efficiency, even with lightweight, can be obtained, and the radiator having a desired shape can be easily manufactured.

In two or more laminates included in the present radiator, sizes may be different from or identical to each other, respectively. If the laminates having different sizes are used, the radiator excellent in the heat dissipation efficiency tends to be easily formed.

The size (longitudinal and transverse length) of the laminate is not particularly limited, and may be appropriately selected according to the desired application.

The size (thickness) of the laminate is not particularly limited, but in view of, for example, capability of easily forming the radiator having a desired shape, the laminate preferably has flexibility. Further, in consideration of bending, shape retention, the heat dissipation characteristics and so forth of the laminate, the thickness is ordinary 40 to 400 micrometers, preferably 40 to 300 micrometers, and further preferably 100 to 200 micrometers.

In addition, an expression “the laminate has flexibility” means a laminate in which the graphite sheet is not broken in folding the laminate, and the heat dissipation performance is hard to reduce.

The laminate is ordinarily a plate-shaped body having a uniform surface, but may have holes or slits opened, or may be embossed or notched according to the desired application.

The laminate is not particularly limited as long as the laminate includes the metal foil, the graphite sheet and the metal foil in that order, and may include three or more layers of metal foil, two or more layers of graphite sheets or any other layer than the layers according to the desired application. Presence of the graphite sheet on the surface of the laminate is not preferred in view of suppression of scattering and falling of graphite powder.

Moreover, in the laminate, the graphite sheet may be wrapped with one sheet of metal foil so as to cover the graphite sheet.

As any other layer described above, an adhesive layer is ordinarily used.

The adhesive layer is ordinarily poor in thermal conductivity, and therefore is preferably not used or has a small thickness as much as possible. In consideration of no use of the adhesive layer as much as possible, the laminate in which the graphite sheet is interposed by the metal foil through the adhesive layer or the laminate in which the graphite sheet is wrapped with the metal foil is preferred.

### Graphite Sheet

The graphite sheet is preferably a natural graphite sheet or an artificial graphite sheet.

The heat dissipation performance of the present radiator tends to be significantly influenced by the surface area of the laminate. A commercially available natural graphite sheet is manufactured according to a continuous process, and therefore a sheet having a larger area can be easily obtained in comparison with the artificial graphite sheet that can be manufactured only according to a batch process. Accordingly, the radiator having a large area can be easily manufactured by using the natural graphite sheet, and the radiator having the high heat dissipation performance can be obtained. On the other hand, the artificial graphite sheet is ordinarily obtained by thermally decomposing a polymer film of polyimide or the like. The artificial graphite sheet has remarkably higher thermal conductivity than the natural graphite sheet has, and therefore the radiator having high heat dissipation performance can be obtained.

In the graphite sheet, thermal conductivity of the sheet in the in-plane direction is preferably 500 W/m·K or more, preferably 600 W/m·K or more, and further preferably 700 W/m·K or more.

The heat dissipation performance of the present radiator tends to be significantly influenced by a heat flow rate of the laminate. Accordingly, the radiator having high heat dissipation performance even with a small thickness can be obtained by using the graphite sheet having large thermal conductivity of the sheet in the in-plane direction.

The thermal conductivity of the graphite sheet in the in-plane direction is measured by measuring the thermal diffusivity, specific heat and density by a laser flash or xenon flash thermal-diffusivity measuring device, a DSC and an Archimedes method, respectively, and multiplying the measured values.

A thickness of the graphite sheet is not particularly limited, but in consideration of bending, shape retention, the heat dissipation characteristics and so forth of the laminate, the thickness is ordinarily 10 to 200 micrometers, and preferably 20 to 150 micrometers.

If the graphite sheet having the thickness equal to or greater than an upper limit of the range is used, the sheet may be broken, and liable to be unable to be bent.

### Metal Foil

Commercially available metal foil can be used as the metal foil. As such metal foil, copper foil, aluminum foil, titanium foil or magnesium foil is preferred. The copper foil and the aluminum foil are satisfactory in the thermal conductivity and easily obtained, and therefore are preferred. Moreover, the titanium foil and the magnesium foil are satisfactory in corrosion resistance, and therefore are preferred.

In addition, the metal foil may be foil composed of one kind of metal or foil composed of an alloy.

A kind of the metal foil existing on both surfaces of the graphite sheet in the laminate may be identical to or different from each other, but is preferably identical to each other.

Moreover, a thickness of the metal foil existing on both surfaces of the graphite sheet may be identical to or different from each other.

The thickness of the metal foil is preferably smaller than the thickness of the graphite sheet in view of improvement in the heat dissipation characteristics. Specifically, the thickness is preferably 3 to 100 micrometers in view of capability of obtaining a radiator having ease of availability and ease of processability and excellent heat dissipation efficiency. In particular, the thickness is preferably 10 to 50 micrometers in view of further ease of processability.

### Adhesive Layer

The adhesive layer is not particularly limited as long as the metal foil and the graphite sheet can be adhered, and specific examples thereof include a layer including an acrylic resin, an epoxy resin, a polyolefin, a polyvinyl alcohol, a vinyl acetate copolymer, a polyvinylidene fluoride, a polyester or a polyvinyl acetal. As the adhesive layer, a layer including a polyvinyl acetal, an epoxy resin or the like is preferred because adhesiveness between the metal foil and the graphite sheet is satisfactory, and a layer including a polyvinyl formal which is excellent in adhesiveness and the heat dissipation characteristic even with a small thickness, and further a layer composed of a polyvinyl formal are particularly preferred.

A filler such as alumina, zinc oxide, graphite, boron nitride and silicate may be appropriately added to the adhesive layer in order to adjust characteristics such as the thermal conductivity.

A thickness of the adhesive layer is not limited as long as the metal foil and the graphite sheet are not peeled off, but in consideration of the heat dissipation characteristics of the obtained radiator, the thickness is preferably as small as possible. In view of the thickness of the metal foil and the graphite sheet, the thickness in the range of 0.5 to 4.0 micrometers is practically easy to adopt.

### Heat Dissipation Coating Layer

The heat dissipation fin preferably has a heat dissipation coating layer including orthorhombic silicate and a resin binder on at least part of the surface layer of the heat dissipation fin for the purpose of facilitating heat dissipation by radiation from the surface.

Orthorhombic silicate is used as far-infrared radiant ceramics, and therefore the heat dissipation coating layer including orthorhombic silicate has characteristics particularly excellent in far-infrared radiating properties, and therefore a radiator superb in thermal radiation properties can be obtained by using the heat dissipation coating layer.

The heat dissipation coating layer may exist wholly on the surface layer of the heat dissipation fin, but may partially exist. Examples of an expression “partially exist” include a case of wholly covering one surface (a surface having the largest area) of the surface layer of the laminate, a case of covering part of one surface, a case of covering part of both surfaces, and a case of covering only end surfaces.

When the heat dissipation coating layer is used, in view of capability of obtaining a radiator excellent in the heat dissipation characteristics and the like, the heat dissipation coating layers preferably exist on both surface (two surfaces having the largest area) of the surface layer of the heat dissipation fin, and in view of capability of suppressing scattering or falling of graphite powder and the like, the heat dissipation coating layer preferably exists on the end surfaces of the heat dissipation fin, and in view of having both effects and the like, the heat dissipation coating layer further preferably exists wholly on the surface layer of the heat dissipation fin.

A thickness of the heat dissipation coating layer is preferably at a degree at which a thermal resistance value is not increased, and heat can be sufficiently radiated. The thickness of the heat dissipation coating layer is preferably at a level in which a radiation factor of heat in the obtained radiator becomes high, and specifically, the thickness is selected from 5 to 200 micrometers. The thickness is preferably 10 micrometers or more because radiation performance becomes satisfactory, and is preferably 70 micrometers or less because the thermal resistance value becomes small.

### Orthorhombic Silicate

The orthorhombic silicate has characteristics being lightweight, excellent in the thermal radiation properties, chemically stable, high in compatibility with the resin binder, little harmful on a human body and the like, and therefore is preferably used in the embodiment of the invention.

The orthorhombic silicate is not particularly limited, and may be any of a natural product and an artificial product, and may be an aluminosilicate mineral or further a silicate compound other than the mineral. As the orthorhombic silicate, cordierite or mullite is preferably used in view of capability of obtaining a radiator superb in the heat dissipation characteristics, and so forth.

The orthorhombic silicate included in the heat dissipation coating layer may be of one kind alone, or of two or more kinds.

A shape of the orthorhombic silicate is not particularly limited, but powdery silicate is ordinarily used.

A mean particle size of the orthorhombic silicate based on a particle size distribution measurement using a laser diffraction/scattering method is preferably 0.01 to 100 micrometers in view of capability of obtaining a radiator superb in the heat dissipation characteristics and so forth.

The orthorhombic silicate is used in an amount of preferably 1 to 80% by weight, and further preferably 15 to 60% by weight in the heat dissipation coating layer.

When the orthorhombic silicate is used in such an amount, silicate powder dropping or the like is hard to be caused, and a radiator that is lightweight and particularly excellent in the thermal radiation properties can be obtained.

### Resin Binder

The resin binder is not particularly limited, but a binder formed by using a fluorine compound and a curing agent is preferred.

The heat dissipation coating layer excellent in weather resistance can be obtained by using such a resin binder.

Specific examples of the fluorine compound include a fluorine-containing monomer and oligomer, and a fluorine-containing polymer having a crosslinkable functional group. The compounds may be fully fluorinated or partially fluorinated, and the polymer may be a copolymer.

Specific examples of the curing agent include an isocyanate compound, a diisocyanate compound, a blocked isocyanate compound, a phenol compound, an acid, a base, a thermal acid generator, an acid anhydride curing agent, and an amine curing agent.

Moreover, as the resin binder, a binder formed by using an acrylic compound and a curing agent (in which at least one of the acrylic compound and the curing agent is silicone-modified) is also preferred.

A heat dissipation coating layer excellent in weather resistance and UV resistance can be obtained by using such a resin binder.

Specific examples of the acrylic compound include an acrylic compound and a methacrylic compound, and also an acrylic polymer having a crosslinkable functional group, and a monomer and an oligomer each having an acryloyl group or a methacryloyl group. An acrylic compound is preferred because a rate of polymerization reaction is high, or a methacrylic compound is preferred because a rate of reaction is lower than the rate of the acrylic compound, but skin irritation is small.

Specific examples of the acrylic compound include polyfunctional (meth)acrylates, epoxy (meth)acrylates, urethane (meth)acrylates, polyester (meth)acrylates and polyether (meth) acrylates.

Specific examples of the silicone-modified acrylic compound include a compound in which the acrylic compounds are silicone-modified.

Specific examples of the curing agent include an isocyanate compound, a diisocyanate compound, a blocked isocyanate compound, a phenol compound, an acid, a base, a thermal acid generator, an acid anhydride curing agent, and an amine curing agent.

Specific examples of the silicone-modified curing agent include a compound in which the compounds are silicone-modified.

A term “silicone-modified” means that a material is modified with silicone, and characteristics of silicone are provided. Thus, a compound may be formed into a silicone-modified (meth)acrylic binder by curing by using the silicone-modified compound or curing agent, and therefore a heat dissipation coating layer having excellent heat resistance and UV resistance can be obtained. “Silicone-modified” may be performed at a degree at which the resulting heat dissipation coating layer produces the advantageous effects of the invention. More specifically, “silicone-modified” may be performed at a degree at which a heat dissipation coating layer having the heat resistance and the UV resistance improved is obtained in comparison with a case where a resin binder without being silicone-modified is used.

The resin binder is used in an amount of preferably 20 to 99% by weight, and further preferably 40 to 85% by weight in the heat dissipation coating layer.

When the resin binder is used in such an amount, a radiator in which silicate powder dropping or the like is hard to be caused, and is lightweight and particularly excellent in the thermal radiation properties can be obtained.

The resin binder included in the heat dissipation coating layer may be of one kind alone or of two or more kinds.

The heat dissipation coating layer is preferably a layer formed by using:

a composition containing at least one kind of orthorhombic silicate mineral selected from cordierite and mullite, a fluorine compound and a curing agent; or

a composition containing at least one kind of orthorhombic silicate mineral selected from cordierite and mullite, an acrylic compound and a curing agent (in which at least one of the acrylic compound or the curing agent is silicone-modified), in view of capability of, for example, obtaining a radiator superb in the heat dissipation characteristics and weather resistance. The radiator having such a heat dissipation coating layer can sufficiently exert the effects over a long period of time even under harder conditions such as outdoors.

In each composition, a conventionally known additive may be contained within the range in which the advantageous effects of the invention are not adversely affected.

### Method for Manufacturing Radiator

A method for manufacturing the present radiator includes the following steps 1 and 2:

step 1: a step of forming two or more laminates including metal foil, a graphite sheet and metal foil in that order;

step 2: step 2A of arranging respective laminates obtained in step 1 in a predetermined shape, and then joining part of adjacent laminates by an adhesive tape, an adhesive, grease or cream solder (hereinafter, the materials are also referred to as “joining agent”), and then folding the laminate in the obtained join material in a place in which the laminate is not joined to form a part in which the respective laminates are not brought into contact with each other; or

step 2B of folding part of the respective laminates obtained in step 1 so as to have a join surface joined with the adjacent laminates and have a part not in contact with the adjacent laminates to each other, and then joining the join surface with a joining agent.

According to such a manufacturing method, a radiator having the desired shape can be easily manufactured.

### Step 1

In step 1, two or more laminates described above are formed.

Such step 1 is not particularly limited, and can be performed by a conventionally known method, but is preferably according to a method in which the adhesive layer is formed on a predetermined place of the metal foil and/or the graphite sheet, and then respective layers are arranged through the adhesive layer so as to obtain the laminate including the metal foil, the graphite sheet and the metal foil in that order, and the respective layers are adhered by applying heat and/or pressure thereto to form the laminate.

Specific examples of the method of forming the adhesive layer include a method in which a desired adhesive solution is applied onto metal foil and/or a graphite sheet, and then the resulting material is dried if necessary, or a method of attaching a double-sided adhesive therebetween.

A general coating method can be selected for applying the adhesive solution. Specifically, spin coating, gravure coating, die coating, bar coating, spray coating, dip coating or the like is preferred. In consideration of mass productivity, gravure coating, die coating, spray coating or the like is preferred.

Specific examples of the method of applying heat and/or pressure thereto include a method using a device capable of heating and/or pressurizing operation, such as a hand press, a heating press, a belt press, a vacuum heating press, a laminator and a hot plate, and the method can be appropriately selected according to the adhesive layer. When a thermoplastic adhesive layer is used, a method using a device capable of heating the layer is preferred, and when a pressure-bondable adhesive layer is used, a method using a device capable of pressurizing the layer is preferred.

As the method of forming the laminate using the heating press, the method disclosed in JP 2012-136022 A may be used.

In addition, for example, when two sheets of metal foil and one graphite sheet are used, adhesion between each metal foil and the graphite sheet may be simultaneous or sequential.

In the step 1, two or more laminates may be formed by the method described above or the like, or two or more laminates may be formed by forming one large laminate and then cutting the obtained laminate into a desired size.

Specific examples of a method of manufacturing the radiator including the heat dissipation fin having the heat dissipation coating layer include:

method (i) of forming a laminate in step 1, and then forming a heat dissipation coating layer on a surface layer thereof, and performing the following step 2 using the laminate with the heat dissipation coating layer;

method (ii) of previously forming a heat dissipation coating layer on metal foil or the like serving as a surface layer upon forming the laminate in step 1, and then forming the laminate using the metal foil with the heat dissipation coating layer, and performing the following step 2 using the obtained laminate with the heat dissipation coating layer; and

method (iii) of forming a heat dissipation coating layer on a desire part on the way of the following step 2 or in a stage in which a desired shape radiator is obtained.

In addition, for the purpose of facilitating heat dissipation from the heat dissipation fin by radiation, a layer obtained by using a commercially available heat dissipation coating is preferably provided on the heat dissipation fin, or a commercially available film is preferably attached thereon, too. Specific examples of such a method of providing the layer and the film thereon include a method similar to methods (i) to (iii).

As the film, in view of ease of availability, a commercially available resin film is preferred, and if the film is provided in consideration of the thermal conductivity, the heat dissipation characteristics of the obtained radiator are improved, and such a film is further preferred. When the present radiator is used under high temperature conditions, the film is preferably a heat-resistant film of polyimide or the like, for example. With regard to a thickness of the film, the film to be formed preferably has an effect of improving the radiation factor of the obtained radiator, and the thickness is ordinarily selected from 5 to 200 micrometers at which the film is easily handled. The thickness is preferably 10 micrometers or more because the radiation performance is satisfactory and handling is easy, and preferably 70 micrometers or less because the thermal resistance value is small.

### Step 2

Step 2 described above is ordinarily performed in either step 2A or step 2B as described above, but step 2A described above may be applied to part of two or more laminates included in the radiator, and step 2B described above may be applied to the remaining laminates.

### Step 2A

In step 2A, the respective laminates obtained in step 1 are arranged in a predetermined shape, and then part of the adjacent laminates is joined with the joining agent (step of forming and joining join surface), and subsequently the laminate in the obtained join material is folded in the place in which the laminate is not joined to form a part (blade portion) in which the respective laminates are not brought into contact with each other (folding step).

An expression “arranging the respective laminates in a predetermined shape” means that, when five laminates 101 to 105 are used, for example, the respective laminates are arranged as shown in FIG. 37 (in the FIG. 37, the respective laminates are arranged to be in ascending order in the size).

In addition, in the arrangement described above, the laminate only may be arranged in the predetermined shape, or the laminate may be arranged in the predetermined shape using the laminate in which the layer obtained by using the joining agent is formed in the place in which the join surface is formed with the adjacent laminates.

The adhesive tape, the adhesive, the grease and the cream solder are not particularly limited, and commercially available items can be used.

Specific examples of the adhesive tape include NeoFix10 made by NICHIEI KAKOH CO., LTD., specific examples of the adhesive include EW2070 made by 3M Japan Limited, specific examples of the grease include SCH-20 made by Sunhayato Corp., and specific examples of the cream solder include SMX-21 made by Sunhayato Corp.

As the joining agent, an adhesive tape or an adhesive is preferred in view of, for example, capability of obtaining a radiator having high heat dissipation performance, while lamination is significantly easy.

A size (longitudinal or transverse length) of the layer obtained by using the joining agent on the above occasion is not particularly limited as long as the respective laminates can be joined, and the shape of the radiator desirably manufactured is changed according to the desired application, and therefore the size can be adjusted to a level in consideration of the shape of the radiator.

For example, when the radiator having the shape as shown in FIG. 1 is desirably manufactured, the size of the layer obtained by using the joining agent can be reduced in comparison with a case of manufacturing the radiator having the shape as shown in FIG. 2.

In addition, the size (thickness) of the layer obtained by using the joining agent is not particularly limited as long as the respective laminates can be joined, but in view of, for example, capability of obtaining a radiator excellent in the heat dissipation characteristics, the layer is preferably as thin as possible, and the thickness is ordinarily preferably 0.5 to 30 micrometers, and further preferably 0.5 to 10 micrometers.

Next, the laminate in the obtained join material is folded in the place in which the laminate is not joined to form the part (blade portion) in which the respective laminates are not brought into contact with each other. A folding angle on the above occasion is not particularly limited, and can be appropriately selected according to the desired application, but the laminate is preferably folded to be in the range described above in the angle with respect to the join surface. For example, when the folding angle is about 90 degrees, the radiator having the shape shown in FIG. 1 is obtained according to the step 2A.

Even when the laminate is folded at about 90 degrees, for example, the radiator having the shape as shown in FIG. 1 or the radiator having the shape as shown in FIG. 2 can be obtained by changing the place in which the laminate is folded on the above occasion.

Upon folding the laminate as described above, the laminate is preferably folded by applying heat and/or pressure thereto. The radiator having a certain degree of shape retention can be obtained by folding the laminate by applying heat and/or pressure thereto.

The method of applying heat and/or pressure thereto is not particularly limited, but a method using a guide is preferred. Specific examples thereof include a method using a press processing machine or a wheel processing machine. In the above method, pressing is preferably performed by sequentially descending a punch toward a fixed mold having a concave groove while feeding the join material.

More specifically, for example, the method disclosed in JP 2010-264495 A or the apparatus disclosed in JP H9-155461 A can be applied thereto.

The heat and/or the pressure to be applied thereto is not particularly limited, and can be appropriately selected according to the laminate (heat dissipation fin) to be used, and is preferably at a degree at which a radiator having a certain degree of shape retention can be obtained.

### Step 2B

In step 2B, part of the respective laminates obtained in step 1 is folded so as to have the join surface joined with the adjacent laminates and the part not in contact with the adjacent laminates to each other (folding step), and then the join surface is joined with the joining agent (joining step).

The step 2B is a step in which the order of the joining step and the folding step in the step 2A is substantially reversed.

For example, in the case of the radiator having the shape as shown in FIG. 1, the step 2B may be a step of folding the laminate having the predetermined size into the substantially concave (channel) shape, arranging the respective laminates, and then providing the joining agent between the respective laminates to join the respective laminates, or a step of folding the laminate having the predetermined size on which the layer having the predetermined size obtained by using the joining agent is formed into the substantially concave (channel) shape, and arranging the respective laminates in such a manner that the layer exists between the respective laminates, and then joining the respective laminates.

The joining step and the folding step in step 2B may be a step similar to the joining step and the folding step in step 2A, respectively.

### Electronic Device and Illumination Device

The electronic device and the illumination device according to the embodiment of the invention each include the present radiator. Specific examples of the electronic device include a chip such as an Application Specific Integrated Circuit (ASIC) to be used for image processing, a television an audio apparatus or the like, Central Processing Unit (CPU) in a personal computer, a smartphone or the like, and a battery such as a lithium-ion secondary battery, a lithium ion capacitor and a nickel-hydrogen battery to be used in an automobile, a cellular telephone or the like.

Specific examples of the illumination device include a Light Emitting Diode (LED) illumination device, and use of the present radiator is effective for the LED having a significantly high calorific value, such as an ultra-high brightness LED.

Specific examples of use example of the present radiator in the electronic device or the illumination device include use by arranging the present radiator 10 in such a manner of contacting with heating unit 50 in the electronic device or the illumination device, as shown in FIG. 36.

When the present radiator is arranged in such a manner of contacting with the heating unit, as shown in FIG. 36, the heat is preferably dissipated from the blade portion by allowing the join surface 30 to closely contact the heating unit in such a manner of directly contacting with the heating unit.

A close contact method in the case of allowing the radiator to closely contact with the heating unit is not particularly limited, but preferably includes a method using an adhesive, a double-sided adhesive tape, a TIM (heat dissipating sheet), grease, putty, lapped flat seam, clip clamp or the like. An adhesive, a double-sided adhesive tape, TIM or the like is preferably used because operation upon fixing the radiator is simple, and the material is lightweight, and an adhesive, a double-sided adhesive tape, TIM, grease or putty is preferably used because heat conduction is satisfactory, and lapped flat seam or clip clamp is preferred because the radiator can be further firmly fixed upon mounting the radiator.

Moreover, for the purpose of improving the thermal conductivity and firmly fixing the radiator, grease, putty, TIM, an adhesive, a double-sided adhesive tape or the like is preferably simultaneously used with lapped flat seam or clip clamp.

In addition, the electronic device and the illumination device preferably have an air cooling apparatus such as a fan because such an apparatus promotes heat dissipation of the present radiator.

### EXAMPLES

The invention will be described in detail using Examples described below. However, the invention is not limited to the content described in Examples below.

Materials used in Examples of the invention are as described below.

### Adhesive Material for Laminate Formation

PVF-K: polyvinyl formal resin, made by JNC Corporation, Vinylec K (trade name)

### Joining Material

NeoFix10: double-sided adhesive sheet, made by NICHIEIKAKO Co., Ltd.

### Adhesive Material Used During Evaluation of Heat Dissipation Characteristics

No. 9885: thermally conductive adhesive transfer tape, made by 3M Japan Limited

### Solvent

NMP: Wako 1^{st} Grade, made by Wako Pure Chemical Industries, Ltd.

### Graphite Sheet

SS500: natural graphite sheet, thickness: 76 μm, made by GrafTECH International Holdings Inc. (thermal conductivity in the plane direction of sheet: 500 W/m·K)

SS600 (trade name): natural graphite sheet, thickness: 127 μm, made by GrafTECH International Holdings Inc. (thermal conductivity in the plane direction of sheet: 600 W/m·K)

### Metal Foil

Aluminum foil: 1N30-0 (trade name), thickness: 20 μm, made by UACJ Foil Corporation

Titanium foil: thickness: 20 μm, made by Nilaco Corporation

Aluminum foil: thickness: 100 μm, made byNilaco Corporation

### Heat Dissipation Coating

A heat dissipating coating containing TR Sealer (trade name, made by ACG Coat-Tech Co., Ltd.), which is an acrylic compound, TR Sealer Curing Agent (made by ACG Coat-Tech Co., Ltd.), which is a silicone-modified curing agent, and SS-1000 (trade name, made by Marusu Glaze Co., Ltd., mean particle size: 1.7 μm), which is synthetic cordierite.

### Example 1

A heat sink and a method of manufacturing the same in Example of the invention include a “lamination step,” a “step of forming laminate with joining layer,” a “pressurizing and joining step” and a “folding step.”

“Lamination step”: Onto 20 μm-thick aluminum foil, a PVF-K solution (solvent: NMP) having a solids concentration of 9.4% by weight was applied to be about 2 μm in a thickness of a layer including the PVF-K after drying. After application thereof, the solvent was sufficiently dried to obtain aluminum foil with an adhesive coating film. Next, two sheets of the obtained aluminum foil with the adhesive coating film were used and laminated in such a manner that the adhesive coating surface was in contact with SS500, and heated, pressurized and joined to obtain a laminate having a structure in which both surfaces of a graphite sheet were interposed with metal foil. In addition, the aluminum foil with the adhesive coating film was prepared according to a method similar to the method described in JP 2013-157599 A to be about 2 μm in the thickness of the layer including PVF-K. Moreover, the thickness of the layer including PVF-K was determined by subtracting a thickness of the aluminum foil itself used from the thickness of the aluminum foil with the adhesive coating layer, by using Digimicro MF-501 and Digimicro Counter TC-101, made by Nikon Corporation.

“Step of forming laminate with joining layer”: The laminate obtained in the lamination step was cut into sizes of 175 mm×60 mm, 165 mm×60 mm, 155 mm×60 mm, 145 mm×60 mm and 135 mm×60 mm to obtain five laminates (defined as laminate 101, laminate 102, . . . to laminate 105 in descending order of length for the laminates). Next, NeoFix 10 was cut into sizes of 45 mm×60 mm, 35 mm×60 mm, 25 mm×60 mm and 15 mm×60 mm to obtain joining layers (defined as joining layer 201, joining layer 202, . . . to joining layer 204 in descending order of length for the joining layers). A laminate with a joining layer was obtained by laminating joining layer 201 on laminate 102, joining layer 202 on laminate 103, and further joining layers 203 and 204 on laminates 104 and 105, respectively, as shown in FIG. 37.

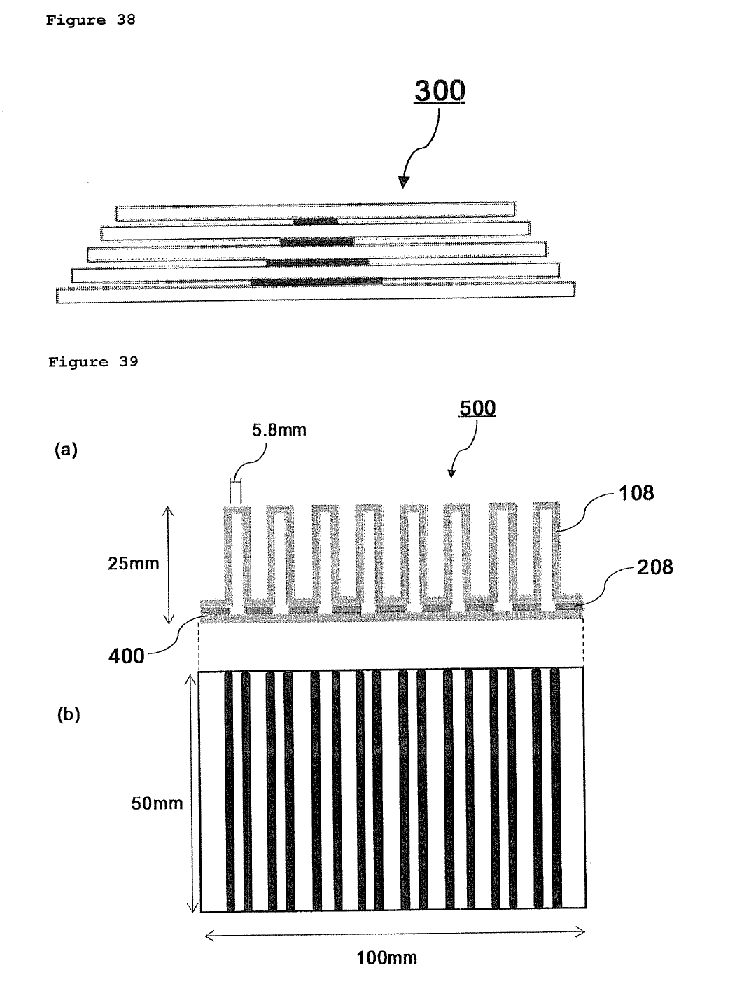

“Pressurizing and joining process”: The laminates with the joining layers obtained in the step of forming laminate with joining layer were arranged to be in order of sizes of the laminates through the joining layers, and then pressurized to obtain join body 300 as shown in FIG. 38.

“Folding process”: Each laminate in the join body obtained in the pressurizing and joining step was folded into the shape as shown in FIG. 1 while a 1 mm-radius round rod was applied thereto to form a blade portion to obtain an objective radiator.

A weight of the obtained radiator was measured using a balance. Table 1 shows the results.

### Evaluation of Heat Dissipation Characteristics

A test body was formed by bonding, by using “No. 9885,” a ceramic heater (Micro ceramic heater MS-3 made by SAKAGUCHI E.H VOC CORP.) on a substantially center portion on a surface on a side opposite to a side on which laminate 101 was in contact with joining layer 201 in the radiator obtained in Example 1. In addition, a K thermocouple (ST-50, made by Rika Kogyo Co., Ltd.) was attached onto the surface on a side opposite to a side on which a heater was in contact with “No. 9885,” and a temperature of the heater was able to be recorded in a personal computer by using a data logger (GL220, made by Graphtec Corporation).

The obtained test body was left to stand in a center of a case covered with a heat insulating material and set at 25° C., the temperature of the heater was confirmed to become constant at 25° C., and then 16.5 V was applied to the heater by using a stabilized direct current power supply for 1,800 seconds, and a temperature on a heater surface at the time was measured. Table 1 shows the results. The heater generates a predetermined amount of heat if the same wattage is applied thereto, and therefore accordingly as a heat dissipating effect of the radiator is higher, the temperature is reduced. More specifically, the radiator in which the temperature of the heater surface is reduced can be reasonably referred to have a higher heat dissipating effect.

### Examples 2 to 6

A radiator was obtained and evaluated in the same manner as in Example 1 except that a laminate and NeoFix 10 were cut so as to obtain a radiator having a size shown in Table 1, and the laminates in the obtained join body were folded so as to obtain the radiator having the size shown in Table 1.

In addition, respective intervals between respective blade portions in the radiator obtained in each Example were identical with the intervals in Example 1.

### Example 7

A radiator was obtained and evaluated in the same manner as in Example 1 except that order of a “pressurizing and joining step” and a “folding step” was interchanged.

### Examples 8 to 10

Laminates 101 to 105 were obtained in Example 1, and then a heat dissipation coating was applied onto one surface (one surface largest in the laminate), both surfaces (two surfaces largest in the laminate), or an end surfaces (a surface other than the largest surface of the laminate) of the laminates 101 to 105, respectively, to be 30 μm in a thickness of a heat dissipation coating layer formed from the coating to prepare a laminate with a heat dissipation coating layer. A radiator was obtained and evaluated in the same manner as in Example 1 except that the obtained laminate with the heat dissipating coating layer was used. A test in which the heat dissipation coating layer was formed on one surface was taken as Example 8, a test in which the heat dissipation coating was formed on both surfaces was taken as Example 9, and a test in which the heat dissipation coating layers were formed on the end surfaces was taken as Example 10.

### Example 11

A radiator was obtained and evaluated in the same manner as in Example 1 except that SS600 was used in place of SS500.

### Example 12

A radiator was obtained and evaluated in the same manner as in Example 1 except that a laminate and NeoFix 10 were cut (in which four laminates and three sheets of NeoFix 10 were prepared) so as to obtain a radiator having a size shown in Table 1, and the laminates in the obtained join body were folded so as to obtain the radiator having the size shown in Table 1.

When viewed from a direction similar to direction A in FIG. 1, respective four intervals between respective blade portions on a right side in the obtained radiator and respective four intervals between respective blade portions on a left side are identical with the intervals in Example 1

### Example 13

A radiator was obtained and evaluated in the same manner as in Example 1 except that titanium foil was used in place of aluminum foil (thickness: 20 μm).

### Comparative Example 1

A heat sink was obtained and evaluated in the same manner as in Example 1 except that 100 μm-thick aluminum foil was used in place of the laminate in the step of forming laminate with joining layer.

### Comparative Examples 2 to 5

A radiator was obtained and evaluated in the same manner as in Example 1 except that 100 μm-thick aluminum foil and NeoFix 10 were cut so as to obtain a radiator having a size shown in Table 1, and the aluminum foils in the obtained join body were folded so as to obtain the radiator having the size shown in Table 1.

Intervals between respective blade portions in the radiator obtained in each Example were identical with the intervals in Example 1.

### Comparative Example 6

A heat sink was obtained and evaluated in the same manner as in Example 1 except that 100 μm-thick aluminum foil was used in place of the laminate in the step of forming laminate with joining layer, and SS500 was used in place of NeoFix 10.

In the heat sink obtained in Comparative Example 6, respective laminates were unable to be joined, and the heat sink was unable to be provided for practical use.

### Comparative Example 7

A laminate was prepared according to a method similar to the method in the lamination step in Example 1. The obtained laminate was cut into a size of about 50 mm×500 mm (laminate A), and the laminate A was corrugated as shown in FIG. 39 while applying a regular quadrangular prism having 5.8 mm in a length of one side of a square. Heat sink 500 was obtained and evaluated by pressurizing and joining, in the same manner as in Example 1, by using the obtained corrugated laminate A (108 in FIG. 39), and aluminum foil (400 in FIG. 39, thickness: 100 μm) having a size of 50 mm×100 mm, and nine sheets of NeoFix10 (208 in FIG. 39) cut into a size of about 50 mm×6 mm, as shown FIG. 39.

### Comparative Example 8

When an evaluation in the same manner as in Example 1 was conducted using a commercially available aluminum heat sink (number of blade portions: 10, thickness of blade portion: 1.2 mm), a heat sink having weight as heavy as 4 times or more was required to be used in order obtain a heater having a surface temperature comparable to the temperatures in Examples.

### Study on Manufacturing Method

Even order of the manufacturing steps was changed, no difference was found in heat dissipation performance.

### Study on Heat Dissipation Coating

Emissivity on a surface of the laminate was improved by applying the heat dissipation coating, and the surface temperature of the heater was reduced. It is considered that, when an area of applying the heat dissipation coating was increased, far infrared rays were able to be efficiently radiated into a space from the surface of the laminate, and therefore the temperature was further reduced.

Graphite powder dropping was also able to be suppressed while improving the heat dissipation performance by applying the heat dissipation coating on the end surfaces of the laminate.

### Study on Graphite Sheet

When a comparison was made between Example 1 in which SS500 was used as the graphite sheet and Example 11 in which SS600 was used as the graphite sheet, the surface temperature of the heater was significantly reduced, although the weight was somewhat increased, by using SS600 having high heat dissipation.

### Study on a Shape

When a comparison was made among Examples 1 to 6, when the radiator having H/L in the above-described range was used, the radiator was found to be superb in the heat dissipation characteristics.

Moreover, when a comparison was made between Example 12 and Comparative Example 7, the radiator in Example 12 resulted in lighter weight, and also further reduction of the surface temperature of the heater, even with the radiators having the same size. The reason is considered that, in Comparative Example 7, only one laminate was used, and the radiator had only the blade portion composed of one laminate, and therefore heat generated in the heater was unable to be efficiently transferred to the fins, or far-infrared rays radiated from an inside of the fin were unable to be efficiently radiated into a space.

### Study on Joining Material

In Comparative Example 6, SS500 was used upon joining the aluminum foil. SS500 has high thermal conductivity in the plane direction, but has no adhesiveness with the aluminum foil, resulting in increasing the surface temperature of the heater.

### Study on Heat Dissipating Speed

The radiators obtained in Examples 1 to 13 were found to be able to quickly transfer the heat generated in a heat source.

Moreover, both bending workability and high thermal conductivity were found to be satisfied without adversely affecting the high thermal conductivity by using the laminate. As described above, when the present radiator is used, the heat in the heating unit switched by ON/OFF and a pulse control is considered to be able to be quickly released, for example.

TABLE 1

| | | | | | | | | Heat |
|---|---|---|---|---|---|---|---|---|
| | | | | | Size of radiator | Heat | | dissipation |
| | | | | | Length × | dissipation | | characteristics |
| | Laminate | | Joining | | width × | coating | Weight | temperature |
| | Metal | Graphite | material | Manufacturing step | height (mm) | layer | (g) | (° C.) |
| Example 1 | Al (20 μm) | SS500 (76 μm) | NeoFix-10 | Pressurizing and joining to folding | 60 × 55 × 60 | None | 11.2 | 85.7 |
| Example 2 | Al (20 μm) | SS500 (76 μm) | NeoFix-10 | Pressurizing and joining to folding | 60 × 55 × 30 | None | 6.5 | 93.7 |
| Example 3 | Al (20 μm) | SS500 (76 μm) | NeoFix-10 | Pressurizing and joining to folding | 60 × 55 × 75 | None | 13.3 | 84.4 |
| Example 4 | Al (20 μm) | SS500 (76 μm) | NeoFix-10 | Pressurizing and joining to folding | 60 × 55 × 90 | None | 15.4 | 82.3 |
| Example 5 | Al (20 μm) | SS500 (76 μm) | NeoFix-10 | Pressurizing and joining to folding | 60 × 55 × 105 | None | 17.5 | 81.1 |
| Example 6 | Al (20 μm) | SS500 (76 μm) | NeoFix-10 | Pressurizing and joining to folding | 60 × 55 × 120 | None | 19.5 | 80.1 |
| Example 7 | Al (20 μm) | SS500 (76 μm) | NeoFix-10 | folding to pressurising and joining | 60 × 55 × 60 | None | 11.2 | 85.7 |
| Example 8 | Al (20 μm) | SS500 (76 μm) | NeoFix-10 | Pressurizing and joining to folding | 60 × 55 × 60 | One | 11.7 | 84.7 |
| | | | | | | surface | | |
| | | | | | | of fin | | |
| Example 9 | Al (20 μm) | SS500 (76 μm) | NeoFix-10 | Pressurizing and joining to folding | 60 × 55 × 60 | Both | 12.3 | 81.9 |
| | | | | | | surfaces | | |
| | | | | | | of fin | | |
| Example 10 | Al (20 μm) | SS500 (76 μm) | NeoFix-10 | Pressurizing and joining to folding | 60 × 55 × 60 | End | 11.3 | 85.2 |
| | | | | | | surface | | |
| Example 11 | Al (20 μm) | SS600 (127 μm) | NeoFix-10 | Pressurizing and joining to folding | 60 × 55 × 60 | None | 16.0 | 80.4 |
| Example 12 | Al (20 μm) | SS500 (76 μm) | NeoFix-10 | Pressurizing and joining to folding | 50 × 100 × 25 | None | 4.8 | 97.8 |
| Example 13 | Ti (20 μm) | SS500 (76 μm) | NeoFix-10 | Pressurizing and joining to folding | 60 × 55 × 60 | None | 15.5 | 86.7 |
| Comparative | Al (100 μm) | — | NeoFix-10 | Pressurizing and joining to folding | 60 × 55 × 60 | None | 12.5 | 91.0 |
| Example 1 | | | | | | | | |
| Comparative | Al (100 μm) | — | NeoFix-10 | Pressurizing and joining to folding | 60 × 55 × 30 | None | 8.0 | 96.6 |
| Example 2 | | | | | | | | |
| Comparative | Al (100 μm) | — | NeoFix-10 | Pressurizing and joining to folding | 60 × 55 × 75 | None | 14.8 | 92.3 |
| Example 3 | | | | | | | | |
| Comparative | Al (100 μm) | — | NeoFix-10 | Pressurizing and joining to folding | 60 × 55 × 90 | None | 17.0 | 90.7 |
| Example 4 | | | | | | | | |
| Comparative | Al (100 μm) | — | NeoFix-10 | Pressurizing and joining to folding | 60 × 55 × 105 | None | 19.3 | 91.0 |
| Example 5 | | | | | | | | |
| Comparative | Al (100 μm) | — | SS500 | Pressurizing and joining to folding | 60 × 55 × 60 | None | 13.3 | >120 |
| Example 6 | | | (76 μm) | | | | | |
| Comparative | Al (20 μm) | SS500 (76 μm) | NeoFix-10 | Corrugating | 50 × 100 × 25 | None | 7.4 | 108.1 |
| Example 7 | | | | | | | | |

### INDUSTRIAL APPLICABILITY

The present radiator is useful in an application requiring heat dissipation, specifically, is useful as a heat dissipating member for an electronic device including a personal computer, and an illumination device including LED or the like, and particularly is useful as the heat dissipating member for the above-described devices in which a heat value is high and high performance is achieved. Moreover, the present radiator is excellent in heat dissipation efficiency, even with lightweight, and therefore is useful as the heat dissipating member for a device that may be transported, or for a transport device such as an automobile or the like.

1. A radiator, comprising two or more heat dissipation fins, wherein,
the heat dissipation fins each are a laminate comprising metal foil, a graphite sheet and metal foil in that order,
all the heat dissipation fins included in the radiator each have a join surface joined with adjacent heat dissipation fins, and a non-contact part not in contact with the adjacent heat dissipation fins to each other, and
at least two of the heat dissipation fins each included in the radiator has a blade portion having a predetermined angle with respect to the join surface in at least part of the non-contact part.

2. The radiator according to claim 1, wherein an area of the non-contact part is larger than an area of the join surface in all the heat dissipation fins included in the radiator.

3. The radiator according to claim 1, wherein a ratio (H/L) of a maximum length H of the radiator in a direction substantially perpendicular to the join surface to a maximum length L thereof in a direction substantially horizontal to the join surface is 1.0 or more.

4. The radiator according to claim 1, wherein the laminate has flexibility.

5. The radiator according to claim 1, wherein the predetermined angle is 30 to 150 degrees.

6. The radiator according to claim 1, wherein the heat dissipation fin is formed by folding the laminate, and has a substantially L shape, a substantially U shape, a substantially concave shape or a substantially fan shape when a state of folding the heat dissipation fin is viewed from the front.

7. The radiator according to claim 1, wherein all the heat dissipation fins included in the radiator are joined with adjacent heat dissipation fins using an adhesive tape, an adhesive, grease or cream solder.

8. The radiator according to claim 1, wherein the graphite sheet is a sheet made of natural graphite or artificial graphite.

9. The radiator according to claim 1, wherein thermal conductivity of the graphite sheet in an in-plane direction in the graphite sheet is 500 W/m·K or more.

10. The radiator according to claim 1, wherein the metal foil is copper, aluminum, titanium or magnesium foil.

11. The radiator according to claim 1, wherein a thickness of the metal foil is smaller than a thickness of the graphite sheet.

12. The radiator according to claim 1, wherein the heat dissipation fin has a heat dissipation coating layer comprising orthorhombic silicate and a resin binder on at least part of a surface layer thereof.

13. The radiator according to claim 12, wherein the heat dissipation coating layer is a layer formed by using:
a composition comprising at least one kind of orthorhombic silicate selected from cordierite and mullite, a fluorine compound and a curing agent; or
a composition comprising at least one kind of orthorhombic silicate selected from cordierite and mullite, an acrylic compound and a curing agent, in which at least one of the acrylic compound and the curing agent is silicone-modified.

14. An electronic device, comprising the radiator according to claim 1.

15. An illumination device, comprising the radiator according to claim 1.

16. A method for manufacturing the radiator according to claim 1, comprising the following steps 1 and 2:
step 1: forming two or more laminates comprising metal foil, a graphite sheet and metal foil in that order; and
step 2: arranging respective laminates obtained in step 1 in a predetermined shape, and then joining part of adjacent laminates by using an adhesive tape, an adhesive, grease or cream solder, and then folding the laminate in the obtained join material in a place in which the laminate is not joined to form a part in which respective laminates are not brought into contact with each other; or
folding part of respective laminates obtained in step 1 so as to have a join surface joined with the adjacent laminates and a part in which the respective laminates are not brought into contact with each other, and then joining the join surface by using an adhesive tape, an adhesive, grease or cream solder.

17. The radiator according to claim 2, wherein a ratio (H/L) of a maximum length H of the radiator in a direction substantially perpendicular to the join surface to a maximum length L thereof in a direction substantially horizontal to the join surface is 1.0 Or more.

18. The radiator according to claim 2, wherein the laminate has flexibility.

19. The radiator according to claim 3, wherein the laminate has flexibility.

20. The radiator according to claim 2, wherein the predetermined angle is 30 to 150 degrees.
